(19) United States
(12) Patent Application Publication
(10) Pub. No.: US 2007/0039641 A1
(43) Pub. Date: Feb. 22, 2007

(54) Cobalt oxide thermoelectric compositions and uses thereof

(76) Inventors: Yufeng Hu, Patchogue, NY (US); Qiang Li, Setauket, NY (US); Weidong Si, Middle Island, NY (US)

Correspondence Address: BROOKHAVEN SCIENCE ASSOCIATES/;BROOKHAVEN NATIONAL LABORATORY, BLDG. 475D - P.O. BOX 5000, UPTON, NY, 11973, US

(21) Appl. No.: 11/207,148

(22) Filed: Aug. 19, 2005

(51) Int. Cl. H01L 35/16

(52) U.S. Cl. 136/238

(57) ABSTRACT

The present invention relates to thermoelectric cobalt oxide compositions and their use in thermal management and generation of electrical power. The invention particularly relates to thin films of these cobalt oxide compositions on a variety of substrates, particularly silicon-group substrates.

This invention was made with Government support under contract number DE-ACO₂-98CH10886, awarded by the U.S. Department of Energy. The Government has certain rights in the invention.

The present invention relates to thermoelectric cobalt oxide compositions and their use in thermal management and generation of electrical power.

### BACKGROUND OF THE INVENTION

The advantages of thermoelectric devices are multifold. Accordingly, there is great interest in applying thermoelectric devices to a wide range of applications.

Of particular relevance are thermoelectric devices which convert heat into electric power, i.e., thermoelectric generators. Thermoelectric generators are attractive from an environmental conservation standpoint since they can recover electrical energy from sources of waste heat. Even further, thermoelectric generators can recover such energy without using any moving parts and without producing any emissions.

Thermoelectric devices can also be used for thermal management of other devices. For example, when electric power is applied to a thermoelectric material, a temperature gradient occurs in the thermoelectric material. The temperature gradient can be advantageously used for cooling or heating a device. When cooling a device, the thermoelectric device is also known as a Peltier refrigerator.

Thermoelectric devices contain one or more thermoelectric materials which provide thermoelectric properties. Accordingly, the quality of the thermoelectric material is critical to the functioning of the thermoelectric device.

Of particular interest are films, and particularly, thin films, of thermoelectric materials. Such thin films have additional advantages, such as, for example, more convenient integration into electronic and semiconductor devices. For example, thin-film thermoelectric devices hold promise for regulating the temperature of microelectronics processors and for conducting thermochemistry experiments on the microscale level.

However, widespread commercial use of such thin-film thermoelectric devices has been hampered by limitations of current thermoelectric materials. Accordingly, there continues to be an ongoing effort to overcome these limitations by improving the properties of such thermoelectric materials.

One of the most important properties of a thermoelectric material is its Seebeck coefficient (S). The Seebeck coefficient, also known as the material's thermoelectric power rating, is a ratio of voltage drop to change in temperature in the material. The units of the Seebeck coefficient can be expressed as microvolts per degrees Kelvin (μV/K) for a particular temperature of interest. A higher Seebeck coefficient is typically indicative of a better thermoelectric material.

The quality of a thermoelectric material is conveniently quantified by the thermoelectric figure of merit Z=S²/ρκ, where S is the Seebeck coefficient, T is the temperature in Kelvin, ρ is the electrical resistivity, and κ is the thermal conductivity. The thermoelectric figure of merit is typically in units of 1/°K.

Since the figure of merit is dependent on temperature, a more convenient expression for quantifying the thermoelectric material is the dimensionless figure of merit ZT, where ZT=S²T/ρκ. The dimensionless figure of merit describes the material's thermoelectric efficiency at a particular temperature of interest, T.

The higher the figure of merit, the better the thermoelectric material. Accordingly, it is desirable for a thermoelectric material to have a high Seebeck coefficient, low electrical resistivity ρ (or conversely, high electrical conductivity σ), and low thermal conductivity κ. More specifically, it is preferable for a thermoelectric material to have ZT>1.

Another parameter which conveniently describes the efficiency of a thermoelectric material is the thermoelectric power factor. The thermoelectric power factor, defined as the electrical conductivity times the square of the Seebeck coefficient, S²σ, is typically expressed in units of watts per meter per square of Kelvin temperature (W/mK²) or microwatts percentimeter per square of Kelvin temperature (μW/cmK²). The thermoelectric power factor is dependent on temperature, and is thus, expressed as a value at a given temperature.

A highly promising class of thin-film thermoelectric materials is the class of layered cobalt oxides, also known as the layered cobaltates. The layered cobaltates typically contain layers of material composition CoO₂ intercalated between layers of another composition. The CoO₂ layer is typically in the form of a CdI₂-type triangular lattice. The other layers can have, for example, a rock salt structure.

Thin films of the layered cobaltates have shown a unique combination of extraordinarily high thermoelectric power and metallic transport properties. Among the layered cobaltates, Ca₃Co₄O₉ (“Co-349”) has been shown to have one of the highest thermoelectric power ratings in single crystal form.

Thin films of cobaltates have been grown on various substrates, such as MgO, SrTiO₃, yttria-stabilized zirconia (YSZ), TiO₂, and Al₂O₃. See, for example, H. Minami, et al., Applied Surface Science, 197-198, pp. 442-447 (2002); I. Matsubara, et al., Applied Physics Letters, 80, pp. 4729-4731 (2002); Y. Yoshida, et al., Journal of the Ceramic Society of Japan, 110 (12), pp. 1080-1083 (2002); and H. W. Eng, et al., Journal of Applied Physics, 97, 013706 (2005).

For example, epitaxial films of the layered cobaltite Na_{0.83}CoO₂ have been grown on a (0001)-oriented α-Al₂O₃ substrate and reported to have a resistivity of 0.86 mOhm.cm, a thermoelectric power of 117 μV/K, and a thermoelectric power factor of 1.6×10⁻³ W/m.K² (16 μW/cm.K²) at 300 K. See H. Ohta, et al., Crystal Growth and Design, vol. 5, no. 1, pp. 25-28 (2005).

However, the thermoelectric properties of thin-film layered cobaltates will need to be significantly improved in order for them to be commercially viable. For example, currently known thin-film cobaltates tend to have an unsatisfactorily high electrical resistivity ρ or low thermoelectric power S, or a combination thereof.

As shown above, improving these characteristics would enhance the thermoelectric properties of the material. Particularly advantageous would be a thermoelectric cobaltate film having a thermoelectric power factor greater than 16 μW/cm.K² at 300 K.

In addition, it would be highly advantageous to make thin films of such layered cobaltates on more commercially relevant substrates, most notably silicon and related materials. Such substrates would make thin films of layered cobaltates more integratable into a variety of electronic and advanced devices, including microelectronic, semiconductor, and microelectromechanical (MEM) devices.

The present inventors recently reported the first known deposition of thin films of layered cobaltates on a silicon substrate. See Y. F. Hu, et al., Applied Physics Letters, 86, 082103 (2005).

Accordingly, there is a need for improved thermoelectric thin films, as well as a need for having such films on commercially relevant substrates. The present invention relates to such thermoelectric thin film compositions.

### SUMMARY OF THE INVENTION

In one aspect, the invention relates to cobalt oxide films having thermoelectric properties. The cobalt oxide film can be, for example, non-crystalline (amorphous), single crystalline, or non-single crystalline. Some particularly preferred non-single crystalline forms for the film include polycrystalline forms and forms in which the film has one or a combination of randomly oriented axes or planes.

The cobalt oxide film is preferably layered. In a preferred embodiment, the layers have a composition according to the formula Co_{1-y}T_{y}O₂ (1). In formula (1), T represents one or a combination of metal atoms, and more preferably, one or a combination of metal atoms selected from the main group, transition and rare earth classes of metals. The subscript y represents 0 or a value greater than 0 and less than 1 for the sum of T.

For example, the cobalt oxide film can have a composition according to the formula AₓCo_{1-y}T_{y}O₂ (2). In formula (2), T and y are as described above, and A represents one or a combination of metal atoms, and more preferably, metal atoms selected from the monovalent, divalent, and trivalent classes of metals. The subscript x represents a value greater than 0 and less than or equal to approximately 1 for the sum of A.

Even more preferably, A represents one or a combination of metal atoms selected from the alkali and alkaline earth classes of metals. For example, in some embodiments, A represents lithium, sodium, potassium, magnesium, calcium, or strontium. In other embodiments, A represents a combination thereof, e.g., sodium and strontium; lithium and strontium; sodium and calcium; calcium and strontium; or sodium, calcium, and strontium.

The cobalt oxide film can also have a composition according to the formula [E₂MᵥO₂₊ᵥ]ₚ[Co_{1-y}T_{y}O₂] (3), wherein y is as described above. In formula (3), E preferably represents one or a combination of metal atoms selected from the monovalent and divalent classes of metals. M and T independently represent one or a combination of metal atoms, and more preferably, one or a combination of metal atoms selected from main group, transition, and rare earth classes of metals. The subscript v represents 0, or a value greater than 0 and less than or equal to 1, or a value greater than 1, for the sum of M. The subscript p represents a value greater than 0 and less than or equal to 1.

M more preferably represents one or a combination of transition metal atoms. Even more preferably, M represents one or a combination of first row transition metal atoms, such as cobalt.

E more preferably represents one or a combination of metal atoms selected from the alkali and alkaline earth metals. For example, E can represent one or a combination of alkaline earth metal atoms. In a preferred embodiment, E represents calcium.

In a preferred embodiment of formula (3), the cobalt oxide film has a composition according to the formula [Ca₂CoᵥO₂₊ᵥ]ₚ[CoO₂] (4), wherein p is as described above, and v represents 0, or a value greater than 0 and less than or equal to 1, or a value greater than 1.

More preferably, v in formula (4) is approximately 1 and p is in a range of approximately 0.6 to 0.7. Even more preferably, p is approximately 0.62, which corresponds to a composition of approximate empirical formula Ca₃Co₄O₉.

The cobalt oxide film is preferably on a suitable substrate. In a preferred embodiment, the substrate is a silicon-group substrate, e.g., a substrate including silicon and/or germanium. For example, the substrate can include an oxide, sulfide, selenide, telluride, nitride, phosphide, arsenide, antimonide, carbide, germanide, stannide, boride, aluminide, gallide, indide, or halide, of silicon; and/or an oxide, sulfide, selenide, telluride, nitride, phosphide, arsenide, antimonide, carbide, silicide, stannide, boride, aluminide, gallide, indide, or halide, of germanium; or a combination thereof.

In particularly preferred embodiments, the substrate is composed of zerovalent silicon, silicon oxide, or a combination of zerovalent silicon and silicon oxide.

The thermoelectric cobalt oxide film can have any suitable thermoelectric power factor. In a preferred embodiment, the cobalt oxide film has a thermoelectric power factor of, or greater than, approximately 2 μW/cmK² at approximately room temperature. In a more preferred embodiment, the cobalt oxide film has a thermoelectric power factor of, or greater than, approximately 16 μW/cmK² at approximately room temperature.

In another aspect, the invention relates to a thermal management or thermoelectric generator device. The device includes (i) a thermoelectric component containing the cobalt oxide film described above, preferably coated onto a silicon-group substrate; and (ii) electrically conductive contacts connected to the thermoelectric component.

In another aspect, the invention relates to methods for altering the thermal characteristics of a device. The method includes (i) supplying a thermoelectric component containing the cobalt oxide film with an electrical current capable of producing a suitable thermal response in the thermoelectric component; and (ii) providing a mode of heat transfer between the thermoelectric component and the device.

In another aspect, the invention relates to methods for generating electrical energy from a heat source. The method includes providing a mode of heat transfer between a thermoelectric component containing the cobalt oxide film and a heat source, thereby generating electrical energy in the thermoelectric component.

In a further embodiment, the electricity generation method includes connecting the thermoelectric component with an electrical power receiver capable of using or storing electrical energy generated by the thermoelectric component.

In another aspect, the invention relates to methods for growing a variety of oxide films on silicon-group substrates. The method includes depositing an oxide film on a silicon-group substrate which is pre-coated with a buffer oxide layer having a cobalt oxide composition.

As a result of the present invention, cobalt oxide films having improved thermoelectric properties can be made possible. In addition, the present invention provides compositions and methods which promote the integration of thermoelectric cobalt oxide films into a variety of technologically advanced devices.

### BRIEF DESCRIPTION OF THE FIGURES

FIG. 1. XRD patterns for a 2300 Å-thick Ca₃Co₄O₉ film grown on single-crystalline Si (100) substrate.

FIG. 2. (a) HREM overview image of the Ca₃Co₄O₉/Si interface region for the film grown on Si (100) substrate, showing the atomic Ca₃Co₄O₉ layered structure and single-crystalline Si structure. (b) The HREM image of the Ca₃Co₄O₉ film grown on Si (100) substrate, demonstrating good crystallinity of the Ca₃Co₄O₉ film.

FIG. 3. Temperature dependence of the resistivity ρ for the Ca₃Co₄O₉ film grown on Si (100) substrate.

FIG. 4. Thermoelectric power as a function of temperature for a Ca₃Co₄O₉ film on Si (100) substrate and a Ca₃Co₄O₉ polycrystalline sample.

### DETAILED DESCRIPTION OF THE INVENTION

The invention relates, generally, to thermoelectric films having a cobalt oxide composition. The cobalt oxide composition has thermoelectric properties, and is composed, minimally, of cobalt and oxygen atoms.

In a preferred embodiment, the thermoelectric cobalt oxide composition is layered. Preferably, the layers are composed, minimally, of cobalt and oxygen atoms. The composition of the cobalt oxide layers can be conveniently represented by the formula
Co_{1-y}T_{y}O₂ (1)

In formula (1), T represents one or a combination of metal atoms other than cobalt. A combination of metal atoms in T includes two or more different kinds of metal atoms. Such a combination of metal atoms can include two, three, four, or a higher number of different kinds of metal atoms.

The subscript y represents 0 or a value greater than 0 and less than 1 for the sum of T. Some examples of suitable values for y include 0.001, 0.01, 0.1, 0.2, 0.25, 0.3, 0.4, 0.5, 0.6, 0.7, 0.75, 0.8, 0.9, 0.95, 0.97, 0.98, 0.99, 0.995, 0.999, and so on. When y represents 0, formula (1) reduces to CoO₂. When y is other than 0, one or a combination of metal atoms (T) is included. When T represents more than one metal, the sum of the molar amounts of the metals in T (i.e., the sum of the subscripts of the metals in T) is equal to the value of y.

Some classes of metals suitable for T include the alkali, alkaline earth, main group, transition, and rare earth (i.e., lanthanide and actinide) classes of metals. More preferably, T represents one or a combination of metals selected from the main group, transition, and rare earth classes of metals.

Some examples of alkali metals suitable for T include lithium (Li), sodium (Na), potassium (K), and rubidium (Rb).

Some examples of alkaline earth metals suitable for T include lithium beryllium (Be), magnesium (Mg), calcium (Ca), and strontium (Sr).

Some examples of main group metals suitable for T include boron (B), aluminum (Al), gallium (Ga), indium (In), carbon (C), silicon (Si), germanium (Ge), nitrogen (N), phosphorus (P), arsenic (As), antimony (Sb), sulfur (S), selenium (Se), and tellurium (Te).

Some examples of rare earth metals suitable for T include lanthanum (La), cerium (Ce), neodymium (Nd), samarium (Sm), europium (Eu), gadolinium (Gd), terbium (Tb), holmium (Ho), erbium (Er), thulium (Tm), ytterbium (Yb), thorium (Th), proctactinium (Pa), uranium (U), and americium (Am).

Some examples of classes of transition metals suitable for T include the first row, second row, and third row transition metals.

The first row transition metals refer to the row of transition metals starting with scandium (Sc) and ending with zinc (Zn). Some examples of suitable first row transition metals include titanium (Ti), vanadium (V), chromium (Cr), manganese (Mn), iron (Fe), cobalt (Co), nickel (Ni), copper (Cu), and zinc (Zn).

The second row transition metals refer to the row of transition metals starting with yttrium (Y) and ending with cadmium (Cd). Some examples of suitable second row transition metals include zirconium (Zr), niobium (Nb), molybdenum (Mo), technetium (Tc), ruthenium (Ru), rhodium (Rh), palladium (Pd), silver (Ag), and cadmium (Cd).

The third row transition metals refer to the row of transition metals starting with hafnium (Hf) and ending with mercury (Hg). Some examples of suitable third row transition metals include tantalum (Ta), tungsten (W), rhenium (Re), osmium (Os), iridium (Ir), platinum (Pt), and gold (Au).

More preferably, T represents one or more first row transition metals selected from titanium, vanadium, chromium, manganese, iron, nickel, copper, and zinc.

Some examples of molar composition formulas for the cobalt oxide layer according to formula (1) include the formulas Co_{0.05}T_{0.95}O₂, Co_{0.1}T_{0.9}O₂, Co_{0.2}T_{0.8}O₂, Co_{0.3}T_{0.7}O₂, Co_{0.4}T_{0.6}O₂, Co_{0.5}T_{0.5}O₂, Co_{0.6}T_{0.4}O₂, Co_{0.7}T_{0.3}O₂, Co_{0.8}T_{0.2}O₂, Co_{0.9}T_{0.1}O₂, Co_{0.95}T_{0.05}O₂, Co_{0.98}T_{0.02}O₂, and Co_{0.99}T_{0.01}O₂, wherein T represents one or a combination of any of the metals described above, and more preferably, one or a combination of the first row transition metals.

Some examples of suitable cobalt oxide layer compositions according to formula (1) wherein T represents a single metal include Co_{0.1}Mn_{0.9}O₂, Co_{0.5}Mn_{0.5}O₂, Co_{0.8}Mn_{0.2}O₂, Co_{0.9}Mn_{0.1}O₂, Co_{0.95}Mn_{0.05}O₂, Co_{0.98}Mn_{0.02}O₂, Co_{0.1}Fe_{0.9}O₂, Co_{0.5}Fe_{0.5}O₂, Co_{0.8}Fe_{0.2}O₂, Co_{0.9}Fe_{0.1}O₂, Co_{0.95}Fe_{0.05}O₂, Co_{0.98}Fe_{0.02}O₂, Co_{0.1}Ni_{0.9}O₂, Co_{0.5}Ni_{0.5}O₂, Co_{0.8}Ni_{0.2}O₂, Co_{0.9}Ni_{0.1}O₂, Co_{0.95}Ni_{0.05}O₂, Co_{0.98}Ni_{0.02}O₂, Co_{0.1}Cu_{0.9}O₂, Co_{0.5}Cu_{0.5}O₂, Co_{0.8}Cu_{0.2}O₂, Co_{0.9}Cu_{0.1}O₂, Co_{0.95}Cu_{0.05}O₂, Co_{0.98}Cu_{0.02}O₂, and Co_{0.99}Cu_{0.01}O₂.

Some examples of suitable cobalt oxide layer compositions according to formula (1) wherein T represents a combination of metals include Co_{0.5}Mn_{0.3}Fe_{0.2}O₂, Co_{0.5}Mn_{0.2}Fe_{0.3}O₂, Co_{0.8}Mn_{0.1}Fe_{0.1}O₂, Co_{0.9}Mn_{0.05}Fe_{0.05}O₂, Co_{0.5}Mn_{0.3}Ni_{0.2}O₂, Co_{0.5}Mn_{0.2}Ni_{0.3}O₂, Co_{0.8}Mn_{0.1}Ni_{0.1}O₂, Co_{0.9}Mn_{0.05}Ni_{0.05}O₂, Co_{0.5}Mn_{0.3}Cu_{0.2}O₂, Co_{0.5}Mn_{0.2}Cu_{0.3}O₂, Co_{0.8}Mn_{0.1}Cu_{0.1}O₂, Co_{0.9}Mn_{0.05}Cu_{0.05}O₂, Co_{0.5}Ni_{0.3}Fe_{0.2}O₂, Co_{0.5}Ni_{0.2}Fe_{0.3}O₂, Co_{0.8}Ni_{0.1}Fe_{0.1}O₂, Co_{0.9}Ni_{0.05}Fe_{0.05}O₂, Co_{0.5}Cu_{0.3}Fe_{0.2}O₂, Co_{0.5}Cu_{0.2}Fe_{0.3}O₂, Co_{0.8}Cu_{0.1}Fe_{0.1}O₂, Co_{0.9}Cu_{0.05}Fe_{0.05}O₂, Co_{0.5}Ni_{0.3}Cu_{0.2}O₂, Co_{0.5}Ni_{0.2}Cu_{0.3}O₂, Co_{0.8}Ni_{0.1}Cu_{0.1}O₂, Co_{0.9}Ni_{0.05}Cu_{0.05}O₂, Co_{0.5}Mn_{0.3}Fe_{0.1}Ni_{0.1}O₂, and Co_{0.7}Fe_{0.1}Ni_{0.1}Cu_{0.1}O₂.

In one embodiment, the thermoelectric cobalt oxide film has a composition according to the formula
AₓCo_{1-y}T_{y}O₂ (2)

In formula (2), T and y have been described above.

The symbol A in formula (2) represents one or a combination of metal atoms. For example, A can be one or a combination of metal atoms selected from the alkali, alkaline earth, main group, transition, and rare earth classes of metals.

More preferably, A in formula (2) represents one or a combination of metal atoms selected from the monovalent, divalent, and trivalent classes of metal atoms. Even more preferably, A represents one or a combination of metals selected from the alkali and alkaline earth classes of metals.

Some examples of monovalent metal atoms suitable for A include the class of monovalent alkali metals. Some examples of monovalent alkali metal atoms include Li⁺¹, Na⁺¹, K⁺¹, and Rb⁺¹. Examples of other suitable monovalent metal atoms include Cu⁺¹, Ag⁺¹, Au⁺¹, and Tl⁺¹.

Some examples of divalent metal atoms suitable for A include the class of divalent alkaline earth metals. Some examples of divalent alkaline earth metal atoms include Be²⁺, Mg²⁺, Ca²⁺, Sr²⁺, and Ba²⁺.

Other classes of divalent metal atoms suitable for A include the divalent transition and rare earth metals. Some examples of divalent transition metal atoms include Mn²⁺, Fe²⁺, Ni²⁺, Cu²⁺, Zn²⁺, Pd²⁺, Cd²⁺, and Pt²⁺. Some examples of divalent rare earth metal atoms include La²⁺, Sm²⁺, Eu²⁺, Tm²⁺, and Yb²⁺.

Some examples of trivalent metal atoms suitable for A include the class of trivalent Group IIIA and Group VA metals. Some examples of Group IIIA trivalent metal atoms include B⁺³, Al⁺³, Ga⁺³, In⁺³, and Tl⁺³. Some examples of Group VA trivalent metal atoms include P⁺³, As⁺³, Sb⁺³, and Bi⁺³. Some examples of trivalent rare earth metal atoms include Ce³⁺, Pr³⁺, Nd³⁺, Sm³⁺, Eu³⁺, Gd³⁺, Tb³⁺, Dy³⁺, Ho³⁺, Er³⁺, Tm³⁺, Yb³⁺, Ac³⁺, Np³⁺, and Am³⁺.

In formula (2), the subscript x represents a value greater than 0 and less than or equal to approximately 1 for the sum of A. Some examples of suitable values for x include 0.001, 0.01, 0.1, 0.2, 0.25, 0.3, 0.4, 0.5, 0.6, 0.7, 0.75, 0.8, 0.9, 0.95, 0.97, 0.98, 0.99, 0.995, 1, 1.1, and 1.2.

Some examples of cobalt oxide compositions according to formula (2) when T is not present (i.e., y is 0) include those represented by the formulas ACoO₂, A_{0.9}CoO₂, A_{0.8}CoO₂, A_{0.75}CoO₂, A_{0.7}CoO₂, A_{0.6}CoO₂, A_{0.5}CoO₂, A_{0.4}CoO₂, A_{0.3}CoO₂, A_{0.25}CoO₂, A_{0.2}CoO₂, A_{0.1}CoO₂, A_{0.05}CoO₂, wherein A represents any one or combination of metals described above, and more preferably, one or a combination of metals selected from the alkali and alkaline earth classes of metals.

Some examples of cobalt oxide compositions according to formula (2) when T is present (i.e., y is other than 0) include those represented by the formulas AₓCo_{0.05}T_{0.95}O₂, AₓCo_{0.1}T_{0.9}O₂, AₓCo_{0.2}T_{0.8}O₂, AₓCo_{0.3}T_{0.7}O₂, AₓCo_{0.4}T_{0.6}O₂, AₓCo_{0.5}T_{0.5}O₂, AₓCo_{0.6}T_{0.4}O₂, AₓCo_{0.7}T_{0.3}O₂, AₓCo_{0.8}T_{0.2}O₂, AₓCo_{0.9}T_{0.1}O₂, AₓCo_{0.95}T_{0.05}O₂, AₓCo_{0.98}T_{0.02}O₂, and AₓCo_{0.99}T_{0.01}O₂, wherein A and x are as defined above, and T represents any one or combination of metals described above, and more preferably, one or a combination of metals selected from the transition and rare earth classes of metals.

For example, one embodiment relates to the class of cobalt oxide compositions according to formula (2) wherein A is sodium. Such cobalt oxide compositions can be represented by the formula NaₓCo_{1-y}T_{y}O₂ (2a). Some specific examples of such compositions include NaCoO₂, Na_{0.9}CoO₂, Na_{0.8}CoO₂, Na_{0.8}Co_{0.5}Cu_{0.5}O₂, Na_{0.8}Co_{0.6}Cu_{0.2}O₂, Na_{0.8}Co_{0.8}Fe_{0.2}O₂, Na_{0.75}CoO₂, Na_{0.7}CoO₂, Na_{0.6}CoO₂, Na_{0.5}CoO₂, Na_{0.4}CoO₂, Na_{0.3}CoO₂, Na_{0.25}CoO₂, Na_{0.2}CoO₂, Na_{0.1}CoO₂, Na_{0.5}Co_{0.5}Mn_{0.5}O₂, Na_{0.5}Co_{0.8}Mn_{0.2}O₂, Na_{0.5}Co_{0.5}Fe_{0.5}O₂, Na_{0.5}Co_{0.9}Fe_{0.1}O₂, Na_{0.5}Co_{0.5}Ni_{0.5}O₂, Na_{0.5}Co_{0.8}Ni_{0.2}O₂, Na_{0.5}Co_{0.9}Ni_{0.1}O₂, Na_{0.5}Co_{0.5}Cu_{0.5}O₂, Na_{0.5}Co_{0.8}Cu_{0.2}O₂, Na_{0.7}Co_{0.9}Cu_{0.1}O₂, Na_{0.5}Co_{0.5}Mn_{0.3}Fe_{0.2}O₂, Na_{0.5}Co_{0.5}Mn_{0.3}Ni_{0.2}O₂, Na_{0.5}Co_{0.5}Mn_{0.3}Cu_{0.2}O₂, Na_{0.5}Co_{0.5}Ni_{0.3}Fe_{0.2}O₂, Na_{0.5}Co_{0.5}Cu_{0.3}Fe_{0.2}O₂, Na_{0.7}Co_{0.5}Ni_{0.3}Cu_{0.2}O₂, Na_{0.7}Co_{0.5}Ni_{0.2}Cu_{0.3}O₂, Na_{0.7}Co_{0.8}Ni_{0.1}Cu_{0.1}O₂, Na_{0.9}Co_{0.5}Mn_{0.3}Fe_{0.1}Ni_{0.1}O₂, and Na_{0.5}Co_{0.7}Fe_{0.1}Ni_{0.1}Cu_{0.1}O₂.

Another embodiment relates to the class of cobalt oxide compositions according to formula (2) wherein A is strontium. Such cobalt oxide compositions can be represented by the formula SrₓCo_{1-y}T_{y}O₂ (2b). Some specific examples of such compositions include SrCoO₂, Sr_{0.9}CoO₂, Sr_{0.8}CoO₂, Sr_{0.8}Co_{0.5}Cu_{0.5}O₂, Sr_{0.8}Co_{0.6}Cu_{0.2}O₂, Sr_{0.8}Co_{0.8}Fe_{0.2}O₂, Sr_{0.75}CoO₂, Sr_{0.75}CoO₂, Sr_{0.7}CoO₂, Sr_{0.6}CoO₂, Sr_{0.5}CoO₂, Sr_{0.4}CoO₂, Sr_{0.3}CoO₂, Sr_{0.25}CoO₂, Sr_{0.2}CoO₂, Sr_{0.1}CoO₂, Sr_{0.5}Co_{0.5}Mn_{0.5}O₂, Sr_{0.5}Co_{0.8}Mn_{0.2}O₂, Sr_{0.5}Co_{0.5}Fe_{0.5}O₂, Sr_{0.5}Co_{0.9}Fe_{0.1}O₂, Sr_{0.5}Co_{0.5}Ni_{0.5}O₂, Sr_{0.5}Co_{0.8}Ni_{0.2}O₂, Sr_{0.5}Co_{0.9}Ni_{0.1}O₂, Sr_{0.5}Co_{0.5}Cu_{0.5}O₂, Sr_{0.5}Co_{0.8}Cu_{0.2}O₂, Sr_{0.7}Co_{0.9}Cu_{0.1}O₂, Sr_{0.5}Co_{0.5}Mn_{0.3}Fe_{0.2}O₂, Sr_{0.5}Co_{0.5}Mn_{0.3}Ni_{0.2}O₂, Sr_{0.5}Co_{0.5}Mn_{0.3}Cu_{0.2}O₂, Sr_{0.5}Co_{0.5}Ni_{0.3}Fe_{0.2}O₂, Sr_{0.5}Co_{0.5}Cu_{0.3}Fe_{0.2}O₂, Sr_{0.7}Co_{0.5}Ni_{0.3}Cu_{0.2}O₂, Sr_{0.7}Co_{0.5}Ni_{0.2}Cu_{0.3}O₂, Sr_{0.7}Co_{0.8}Ni_{0.1}Cu_{0.1}O₂, Sr_{0.9}Co_{0.5}Mn_{0.3}Fe_{0.1}Ni_{0.1}O₂, and Sr_{0.5}Co_{0.7}Fe_{0.1}Ni_{0.1}Cu_{0.1}O₂.

Another embodiment relates to the class of cobalt oxide compositions according to formula (2) wherein A is calcium. Such cobalt oxide compositions can be represented by the formula CaₓCo_{1-y}T_{y}O₂ (2c). Some specific examples of such compositions include CaCoO₂, Ca_{0.9}CoO₂, Ca_{0.8}CoO₂, Ca_{0.8}Co_{0.5}Cu_{0.5}O₂, Ca_{0.8}Co_{0.6}Cu_{0.2}O₂, Ca_{0.8}Co_{0.8}Fe_{0.2}O₂, Ca_{0.75}CoO₂, Ca_{0.7}CoO₂, Ca_{0.6}CoO₂, Ca_{0.5}CoO₂, Ca_{0.4}CoO₂, Ca_{0.3}CoO₂, Ca_{0.25}CoO₂, Ca_{0.2}CoO₂, Ca_{0.1}CoO₂, Ca_{0.5}Co_{0.5}Mn_{0.5}O₂, Ca_{0.5}Co_{0.8}Mn_{0.2}O₂, Ca_{0.5}Co_{0.5}Fe_{0.5}O₂, Ca_{0.5}Co_{0.9}Fe_{0.1}O₂, Ca_{0.5}Co_{0.5}Ni_{0.5}O₂, Ca_{0.5}Co_{0.8}Ni_{0.2}O₂, Ca_{0.5}Co_{0.9}Ni_{0.1}O₂, Ca_{0.5}Co_{0.5}Cu_{0.5}O₂, Ca_{0.5}Co_{0.8}Cu_{0.2}O₂, Ca_{0.7}Co_{0.9}Cu_{0.1}O₂, Ca_{0.5}Co_{0.5}Mn_{0.3}Fe_{0.2}O₂, Ca_{0.5}Co_{0.5}Mn_{0.3}Ni_{0.2}O₂, Ca_{0.5}Co_{0.5}Mn_{0.3}Cu_{0.2}O₂, Ca_{0.5}Co_{0.5}Ni_{0.3}Fe_{0.2}O₂, Ca_{0.5}Co_{0.5}Cu_{0.3}Fe_{0.2}O₂, Ca_{0.7}Co_{0.5}Ni_{0.3}Cu_{0.2}O₂, Ca_{0.7}Co_{0.5}Ni_{0.2}Cu_{0.3}O₂, Ca_{0.7}Co_{0.8}Ni_{0.1}Cu_{0.1}O₂, Ca_{0.9}Co_{0.5}Mn_{0.3}Fe_{0.1}Ni_{0.1}O₂, and Ca_{0.5}Co_{0.7}Fe_{0.1}, Ni_{0.1}Cu_{0.1}O₂.

Another embodiment relates to the class of cobalt oxide compositions according to formula (2) wherein A represents a combination (i.e., two or more) of metals selected from the alkali and alkaline earth classes of metals. Such cobalt oxide compositions can be represented by the formula Aₓ₁Aₓ₂Co_{1-y}T_{y}O₂ (2d) wherein Aₓ₁ and Aₓ₂ each independently represents one or a combination of metals selected from the alkali and alkaline earth classes of metals; T and y are as defined above; and x1 and x2 each independently represents a value of x, as described above.

For example, A in formula (2) can represent a combination of sodium and calcium. Such cobalt oxide compositions can be represented by the formula Naₓ₁Caₓ₂Co_{1-y}T_{y}O₂ (2e). Some specific examples of such compositions when y in formula (2e) is zero include Na_{0.9}Ca_{0.1}CoO₂, Na_{0.8}Ca_{0.2}CoO₂, Na_{0.7}Ca_{0.3}CoO₂, Na_{0.6}Ca_{0.4}CoO₂, Na_{0.5}Ca_{0.5}CoO₂, Na_{0.4}Ca_{0.6}CoO₂, Na_{0.3}Ca_{0.7}CoO₂, Na_{0.2}Ca_{0.8}CoO₂, Na_{0.1}Ca_{0.9}CoO₂, Na_{0.8}Ca_{0.1}CoO₂, Na_{0.7}Ca_{0.2}CoO₂, Na_{0.6}Ca_{0.3}CoO₂, Na_{0.5}Ca_{0.4}CoO₂, Na_{0.4}Ca_{0.5}CoO₂, Na_{0.3}Ca_{0.6}CoO₂, Na_{0.2}Ca_{0.7}CoO₂, Na_{0.1}Ca_{0.8}CoO₂, Na_{0.7}Ca_{0.1}CoO₂, Na_{0.6}Ca_{0.2}CoO₂, Na_{0.5}Ca_{0.3}CoO₂, Na_{0.4}Ca_{0.4}CoO₂, Na_{0.3}Ca_{0.5}CoO₂, Na_{0.2}Ca_{0.6}CoO₂, Na_{0.1}Ca_{0.7}CoO₂, Na_{0.6}Ca_{0.1}CoO₂, Na_{0.5}Ca_{0.2}CoO₂, Na_{0.4}Ca_{0.3}CoO₂, Na_{0.3}Ca_{0.4}CoO₂, Na_{0.2}Ca_{0.5}CoO₂, Na_{0.1}Ca_{0.6}CoO₂, Na_{0.5}Ca_{0.1}CoO₂, Na_{0.4}Ca_{0.2}CoO₂, Na_{0.3}Ca_{0.3}CoO₂, Na_{0.2}Ca_{0.4}CoO₂, Na_{0.1}Ca_{0.5}CoO₂, Na_{0.4}Ca_{0.1}CoO₂, Na_{0.3}Ca_{0.2}CoO₂, Na_{0.2}Ca_{0.3}CoO₂, Na_{0.1}Ca_{0.4}CoO₂, Na_{0.3}Ca_{0.1}CoO₂, Na_{0.2}Ca_{0.2}CoO₂, Na_{0.1}Ca_{0.3}CoO₂, Na_{0.2}Ca_{0.1}CoO₂, Na_{0.1}Ca_{0.2}CoO₂, and Na_{0.1}Ca_{0.1}CoO₂.

In formula (2), A can also represent, for example, a combination of sodium and strontium. Such cobalt oxide compositions can be represented by the formula Naₓ₁Srₓ₂Co_{1-y}T_{y}O₂ (2f). Some specific examples of such compositions when y in formula (2f) is zero include Na_{0.9}Sr_{0.1}CoO₂, Na_{0.8}Sr_{0.2}CoO₂, Na_{0.7}Sr_{0.3}CoO₂, Na_{0.6}Sr_{0.4}CoO₂, Na_{0.5}Sr_{0.5}CoO₂, Na_{0.4}Sr_{0.6}CoO₂, Na_{0.3}Sr_{0.7}CoO₂, Na_{0.2}Sr_{0.8}CoO₂, Na_{0.1}Sr_{0.9}CoO₂, Na_{0.8}Sr_{0.1}CoO₂, Na_{0.7}Sr_{0.2}CoO₂, Na_{0.6}Sr_{0.3}CoO₂, Na_{0.5}Sr_{0.4}CoO₂, Na_{0.4}Sr_{0.5}CoO₂, Na_{0.3}Sr_{0.6}CoO₂, Na_{0.2}Sr_{0.7}CoO₂, Na_{0.1}Sr_{0.8}CoO₂, Na_{0.7}Sr_{0.1}CoO₂, Na_{0.6}Sr_{0.2}CoO₂, Na_{0.5}Sr_{0.3}CoO₂, Na_{0.4}Sr_{0.4}CoO₂, Na_{0.3}Sr_{0.5}CoO₂, Na_{0.2}Sr_{0.6}CoO₂, Na_{0.1}Sr_{0.7}CoO₂, Na_{0.6}Sr_{0.1}CoO₂, Na_{0.5}Sr_{0.2}CoO₂, Na_{0.4}Sr_{0.3}CoO₂, Na_{0.3}Sr_{0.4}CoO₂, Na_{0.2}Sr_{0.5}CoO₂, Na_{0.1}Sr_{0.6}CoO₂, Na_{0.5}Sr_{0.1}CoO₂, Na_{0.4}Sr_{0.2}CoO₂, Na_{0.3}Sr_{0.3}CoO₂, Na_{0.2}Sr_{0.4}CoO₂, Na_{0.1}Sr_{0.5}CoO₂, Na_{0.4}Sr_{0.1}CoO₂, Na_{0.3}Sr_{0.2}CoO₂, Na_{0.2}Sr_{0.3}CoO₂, Na_{0.1}Sr_{0.4}CoO₂, Na_{0.3}Sr_{0.1}CoO₂, Na_{0.2}Sr_{0.2}CoO₂, Na_{0.1}Sr_{0.3}CoO₂, Na_{0.2}Sr_{0.1}CoO₂, Na_{0.1}Sr_{0.2}CoO₂, and Na_{0.1}Sr_{0.1}CoO₂.

In formula (2), A can also represent, for example, a combination of calcium and strontium. Such cobalt oxide compositions can be represented by the formula Caₓ₁Srₓ₂Co_{1-y}T_{y}O₂ (2g). Some specific examples of such compositions when y in formula (2g) is zero include Ca_{0.9}Sr_{0.1}CoO₂, Ca_{0.8}Sr_{0.2}CoO₂, Ca_{0.7}Sr_{0.3}CoO₂, Ca_{0.6}Sr_{0.4}CoO₂, Ca_{0.5}Sr_{0.5}CoO₂, Ca_{0.4}Sr_{0.6}CoO₂, Ca_{0.3}Sr_{0.7}CoO₂, Ca_{0.2}Sr_{0.8}CoO₂, Ca_{0.1}Sr_{0.9}CoO₂, Ca_{0.8}Sr_{0.1}CoO₂, Ca_{0.7}Sr_{0.2}CoO₂, Ca_{0.6}Sr_{0.3}CoO₂, Ca_{0.5}Sr_{0.4}CoO₂, Ca_{0.4}Sr_{0.5}CoO₂, Ca_{0.3}Sr_{0.6}CoO₂, Ca_{0.2}Sr_{0.7}CoO₂, Ca_{0.1}Sr_{0.8}CoO₂, Ca_{0.7}Sr_{0.1}CoO₂, Ca_{0.6}Sr_{0.2}CoO₂, Ca_{0.5}Sr_{0.3}CoO₂, Ca_{0.4}Sr_{0.4}CoO₂, Ca_{0.3}Sr_{0.5}CoO₂, Ca_{0.2}Sr_{0.6}CoO₂, Ca_{0.1}Sr_{0.7}CoO₂, Ca_{0.6}Sr_{0.1}CoO₂, Ca_{0.5}Sr_{0.2}CoO₂, Ca_{0.4}Sr_{0.3}CoO₂, Ca_{0.3}Sr_{0.4}CoO₂, Ca_{0.2}Sr_{0.5}CoO₂, Ca_{0.1}Sr_{0.6}CoO₂, Ca_{0.5}Sr_{0.1}CoO₂, Ca_{0.4}Sr_{0.2}CoO₂, Ca_{0.3}Sr_{0.3}CoO₂, Ca_{0.2}Sr_{0.4}CoO₂, Ca_{0.1}Sr_{0.5}CoO₂, Ca_{0.4}Sr_{0.1}CoO₂, Ca_{0.3}Sr_{0.2}CoO₂, Ca_{0.2}Sr_{0.3}CoO₂, Ca_{0.1}Sr_{0.4}CoO₂, Ca_{0.3}Sr_{0.1}CoO₂, Ca_{0.2}Sr_{0.2}CoO₂, Ca_{0.1}Sr_{0.3}CoO₂, Ca_{0.2}Sr_{0.1}CoO₂, Ca_{0.1}Sr_{0.2}CoO₂, and Ca_{0.1}Sr_{0.1}CoO₂.

Some specific examples of such cobalt oxide compositions when y in formulas (2e), (2f), and (2g) is not zero include Na_{0.5}Ca_{0.5}CoO_{0.5}Mn_{0.5}O₂, Na_{0.5}Ca_{0.2}Co_{0.8}Mn_{0.2}O₂, Na_{0.2}Ca_{0.5}Co_{0.5}Fe_{0.5}O₂, Na_{0.4}Ca_{0.2}Co_{0.8}Fe_{0.2}O₂, Na_{0.5}Ca_{0.5}Co_{0.5}Ni_{0.5}O₂, Na_{0.2}Ca_{0.2}Co_{0.8}Ni_{0.2}O₂, Na_{0.2}Ca_{0.1}Co_{0.9}Ni_{0.1}O₂, Na_{0.7}Ca_{0.2}Co_{0.5}Cu_{0.5}O₂, Na_{0.5}Ca_{0.5}Co_{0.8}Cu_{0.2}O₂, Na_{0.4}Ca_{0.3}Co_{0.8}Cu_{0.2}O₂, Na_{0.2}Ca_{0.5}Co_{0.9}Cu_{0.1}O₂, Na_{0.5}Ca_{0.5}Co_{0.5}Mn_{0.3}Fe_{0.2}O₂, Na_{0.2}Ca_{0.6}Co_{0.5}Mn_{0.3}Ni_{0.2}O₂, Na_{0.4}Ca_{0.4}Co_{0.5}Mn_{0.3}Cu_{0.2}O₂, Na_{0.5}Ca_{0.5}Ni_{0.3}Fe_{0.2}O₂, Na_{0.3}Ca_{0.1}Co_{0.5}Cu_{0.3}Fe_{0.2}O₂, Na_{0.2}Ca_{0.5}Co_{0.5}Ni_{0.3}Cu_{0.2}O₂, Na_{0.2}Ca_{0.5}Co_{0.5}Ni_{0.2}Cu_{0.4}O₂, Na_{0.5}Ca_{0.2}Co_{0.8}Ni_{0.1}Cu_{0.1}O₂, Na_{0.5}Ca_{0.5}Co_{0.5}Mn_{0.3}Fe_{0.1}Ni_{0.1}O₂, Na_{0.5}Ca_{0.5}Co_{0.7}Fe_{0.1}Ni_{0.1}Cu_{0.1}O₂, Na_{0.5}Sr_{0.5}Co_{0.5}Mn_{0.5}O₂, Na_{0.5}Sr_{0.2}Co_{0.8}Mn_{0.2}O₂, Na_{0.2}Sr_{0.5}Co_{0.5}Fe_{0.5}O₂, Na_{0.4}Sr_{0.2}Co_{0.8}Fe_{0.2}O₂, Na_{0.5}Sr_{0.5}Co_{0.5}Ni_{0.5}O₂, Na_{0.2}Sr_{0.2}Co_{0.8}Ni_{0.2}O₂, Na_{0.2}Sr_{0.1}Co_{0.9}Ni_{0.1}O₂, Na_{0.7}Sr_{0.2}Co_{0.5}Cu_{0.5}O₂, Ca_{0.5}Sr_{0.4}Co_{0.5}Mn_{0.5}O₂, Ca_{0.5}Sr_{0.5}Co_{0.5}Cu_{0.5}O₂, Ca_{0.2}Sr_{0.8}Co_{0.8}Cu_{0.2}O₂, Ca_{0.3}Sr_{0.2}Co_{0.5}Ni_{0.5}O₂, and Ca_{0.4}Sr_{0.4}Cu_{0.5}Mn_{0.5}O₂.

In another embodiment, the cobalt oxide film has a composition according to the formula
[E₂MᵥO₂₊ᵥ]ₚ[Co_{1-y}T_{y}O₂] (3)

In formula (3), E represents one or a combination of metal atoms selected from monovalent and divalent metal atoms. The monovalent and divalent metals have been described above. M and T independently represent one or a combination of metal atoms selected from main group, transition, and rare earth classes of metals, all of which have been described above. The subscript y represents 0 or a value greater than 0 and less than 1 for the sum of T.

The subscript v in formula (3) represents 0, or a value greater than 0 and less than or equal to 1, or a value greater than 1, for the sum of M. In a preferred embodiment, v represents a value greater than 0 and less than or equal to 1, or a value greater than 1, for the sum of M. Some examples of suitable values for v include 0.001, 0.01, 0.1, 0.2, 0.25, 0.3, 0.4, 0.5, 0.6, 0.7, 0.75, 0.8, 0.9, 0.95, 0.97, 0.98, 0.99, 0.995, 1, 1.1, 1.2, 1.5, 1.7, 2, 2.5, 3, and so on, for each M or for the sum of M.

The subscript p in formula (3) can be any value greater than 0 and less than or equal to approximately 1. Some examples of suitable values for p include 0.001, 0.01, 0.1, 0.2, 0.25, 0.3, 0.4, 0.5, 0.6, 0.7, 0.75, 0.8, 0.9, 0.95, 0.97, 0.98, 0.99, 0.995, and 1.

In one embodiment of formula (3), E represents one or a combination of metals selected from the alkali and alkaline earth metals. For example, E can represent one or a combination of metals selected from lithium, sodium, potassium, magnesium, calcium, and strontium.

In a further embodiment, M in formula (3) represents a main group metal. Some examples of classes of such compositions when T is not present include [Li₂TlᵥO₂₊ᵥ]ₚ[CoO₂], [Na₂TlᵥO₂₊ᵥ]ₚ[CoO₂], [K₂TlᵥO₂₊ᵥ]ₚ[CoO₂], [(Li_{0.5}Na_{0.5})₂TlᵥO₂₊ᵥ]ₚ[CoO₂], [(Li_{0.2}Na_{0.8})₂TlᵥO₂₊ᵥ]ₚ[CoO₂], [Mg₂TlᵥO₂₊ᵥ]ₚ[CoO₂], [Ca₂TlᵥO₂₊ᵥ]ₚ[CoO₂], [Sr₂TlᵥO₂₊ᵥ]ₚ[CoO₂], [(Mg_{0.5}Ca_{0.5})₂TlᵥO₂₊ᵥ][CoO₂], [(Ca_{0.5}Sr_{0.5})₂TlᵥO₂₊ᵥ]ₚ[CoO₂], [(Li_{0.5}Sr_{0.5})₂TlᵥO₂₊ᵥ]ₚ[CoO₂], [Li₂BiᵥO₂₊ᵥ]ₚ[CoO₂], [Na₂BiᵥO₂₊ᵥ]ₚ[CoO₂], [K₂BiᵥO₂₊ᵥ]ₚ[CoO₂], [(Li_{0.5}Na_{0.5})₂BiᵥO₂₊ᵥ]ₚ[CoO₂], [Mg₂BiᵥO₂₊ᵥ]ₚ[CoO₂], [Ca₂BiᵥO₂₊ᵥ]ₚ[CoO₂], [Sr₂BiᵥO₂₊ᵥ]ₚ[CoO₂], [(Mg_{0.5}Ca_{0.5})₂BiᵥO₂₊ᵥ]ₚ[CoO₂], [(Na_{0.5}Mg_{0.5})₂BiᵥO₂₊ᵥ]ₚ[CoO₂], [(Ca_{0.5}Sr_{0.5})₂BiᵥO₂₊ᵥ]ₚ[CoO₂], [(Ca_{0.9}Sr_{0.1})₂BiᵥO₂₊ᵥ]ₚ[CoO₂], [Li₂PbᵥO₂₊ᵥ]ₚ[CoO₂], [Sr₂PbᵥO₂₊ᵥ]ₚ[CoO₂], [Li₂InᵥO₂₊ᵥ]ₚ[CoO₂], [Ca₂GaᵥO₂₊ᵥ]ₚ[CoO₂], [Cd₂GaᵥO₂₊ᵥ]ₚ[CoO₂], [(Ca_{0.5}Sr_{0.5})₂GaᵥO₂₊ᵥ]ₚ[CoO₂], and [Sr₂GeᵥO₂₊ᵥ]ₚ[CoO₂].

In a further embodiment, M in formula (3) represents a combination of main group metals. Some examples of classes of such compositions include [Li₂(Bi_{0.5}Tl_{0.5})ᵥO₂₊ᵥ]ₚ[CoO₂], [Li₂(Bi_{0.2}Tl_{0.8})ᵥO₂₊ᵥ]ₚ[CoO₂], [Na₂(Bi_{0.5}Tl_{0.5})ᵥO₂₊ᵥ]ₚ[CoO₂], [(Li_{0.5}Na_{0.5})₂(Bi_{0.5}Tl_{0.5})ᵥO₂₊ᵥ]ₚ[CoO₂], [Mg₂(Bi_{0.5}Tl_{0.5})ᵥO₂₊ᵥ]ₚ[CoO₂], [Ca₂(Bi_{0.5}Tl_{0.5})ᵥO₂₊ᵥ]ₚ[CoO₂], [Sr₂(Bi_{0.5}Tl_{0.5})ᵥO₂₊ᵥ]ₚ[CoO₂], [(Mg_{0.5}Ca_{0.5})₂(Bi_{0.5}Tl_{0.5})ᵥO₂₊ᵥ]ₚ[CoO₂], [(Ca_{0.5}Sr_{0.5})₂(Bi_{0.5}Tl_{0.5})ᵥO₂₊]ₚ[CoO₂], [(Ca_{0.8}Sr_{0.2})₂(Bi_{0.5}Tl_{0.5})ᵥO₂₊ᵥ]ₚ[CoO₂], [(Li_{0.5}Sr_{0.5})₂(Bi_{0.5}Tl_{0.5})ᵥO₂₊ᵥ]ₚ[CoO₂], [Li₂(Pb_{0.5}Tl_{0.5})ᵥO₂₊ᵥ]ₚ[CoO₂], [Na₂(Pb_{0.7}Tl_{0.3})ₚO₂₊ᵥ]ₚ[CoO₂], [(Li_{0.4}Na_{0.6})₂(Pb_{0.5}Tl_{0.5})ᵥO₂₊ᵥ]ₚ[CoO₂], [Li₂(In_{0.5}Tl_{0.5})ᵥO₂₊ᵥ]ₚ[CoO₂], [Na₂(In_{0.5}Tl_{0.5})ᵥO₂₊ᵥ]ₚ[CoO₂], [(Li_{0.5}Na_{0.5})₂(In_{0.5}Tl_{0.5})ᵥO₂₊ᵥ]ₚ[CoO₂], [Mg₂(In_{0.5}Tl_{0.5})ᵥO₂₊ᵥ]ₚ[CoO₂], [Ca₂(In_{0.5}Tl_{0.5})ᵥO₂₊ᵥ]ₚ[CoO₂], [Ca₂(In_{0.8}Tl_{0.2})ᵥO₂₊ᵥ]ₚ[CoO₂], [Sr₂(In_{0.5}Tl_{0.5})ᵥO₂₊ᵥ]ₚ[CoO₂], [(Mg_{0.5}Ca_{0.5})₂(In_{0.5}Tl_{0.5})ᵥO₂₊ᵥ]ₚ[CoO₂], [Li₂(Pb_{0.5}Bi_{0.5})ᵥO₂₊ᵥ]ₚ[CoO₂], [Na₂(Pb_{0.5}Bi_{0.5})ᵥO₂₊ᵥ]ₚ[CoO₂], [(Li_{0.5}Na_{0.5})₂(Pb_{0.5}Bi_{0.5})ᵥO₂₊ᵥ]ₚ[CoO₂], [Mg₂(Pb_{0.5}Bi_{0.5})ᵥO₂₊ᵥ]ₚ[CoO₂], [Li₂(In_{0.5}Bi_{0.5})ᵥO₂₊₁]ₚ[CoO₂], [Ca₂(In_{0.5}Bi_{0.5})O₂₊ᵥ]ₚ[CoO₂], [Li₂(Ga_{0.5}In_{0.5})ᵥO₂₊ᵥ]ₚ[CoO₂], [Na₂(Ga_{0.5}In_{0.5})ᵥO₂₊ᵥ]ₚ[CoO₂], [(Li_{0.5}Na_{0.5})₂(Ga_{0.5}In_{0.5})ᵥO₂₊ᵥ]ₚ[CoO₂], [(Li_{0.5}Na_{0.9})₂(Ga_{0.6}In_{0.4})ᵥO₂₊ᵥ]ₚ[CoO₂], [Mg₂(Ga_{0.5}In_{0.5})ᵥO₂₊ᵥ]ₚ[CoO₂], [Ca₂(Ga_{0.5}In_{0.5})ᵥO₁₊ᵥ]ₚ[CoO₂], [Sr₂(Ga_{0.5}In_{0.5})ᵥO₁₊ᵥ]ₚ[CoO₂], [(Na_{0.5}Ca_{0.5})₂(Ga_{0.5}In_{0.5})ᵥO₂₊ᵥ]ₚ[CoO₂], and [Li₂(Bi_{0.2}Tl_{0.4}In_{0.2})ᵥO₂₊ᵥ]ₚ[CoO₂].

In another embodiment, M in formula (3) represents a transition metal, and more preferably, a first row transition metal. Some examples of classes of such compositions include [Li₂VᵥO₂₊ᵥ]ₚ[CoO₂], [Na₂CrᵥO₂₊ᵥ]ₚ[CoO₂], [Li₂MnᵥO₂₊ᵥ]ₚ[CoO₂], [K₂MnᵥO₂₊ᵥ]ₚ[CoO₂], [(Li_{0.5}Na_{0.5})₂FeᵥO₂₊ᵥ]ₚ[CoO₂], [Li₂CoᵥO₂₊ᵥ]ₚ[CoO₂], [Na₂CoᵥO₂₊ᵥ]ₚ[CoO₂], [K₂CoᵥO₂₊ᵥ]ₚ[CoO₂], [(Li_{0.5}Na_{0.5})₂CoᵥO₂₊ᵥ]ₚ[CoO₂], [(Li_{0.4}Na_{0.6})₂CoᵥO₂₊ᵥ]ₚ[CoO₂], [(Li_{0.8}Na_{0.2})₂CoᵥO₂₊ᵥ]ₚ[CoO₂], [Mg₂CoᵥO₂₊ᵥ]ₚ[CoO₂], [Ca₂CoᵥO₂₊ᵥ]ₚ[CoO₂], [Sr₂CoᵥO₂₊ᵥ]ₚ[CoO₂], [(Mg_{0.5}Ca_{0.5})₂CoᵥO₂₊ᵥ]ₚ[CoO₂], [(Ca_{0.5}Sr_{0.5})₂CoᵥO₂₊ᵥ]ₚ[CoO₂], [(Ca_{0.8}Sr_{0.2})₂CoᵥO₂₊ᵥ]ₚ[CoO₂], [(Ca_{0.2}Sr_{0.8})₂CoᵥO₂₊ᵥ]ₚ[CoO₂], [(Li_{0.5}Sr_{0.5})₂CoᵥO₂₊ᵥ]ₚ[CoO₂], [(Na_{0.5}Sr_{0.5})₂CoᵥO₂₊ᵥ]ₚ[CoO₂], [(Li_{0.5}Mg_{0.5})₂CoᵥO₂₊ᵥ]ₚ[CoO₂], [(Na_{0.5}Mg_{0.5})₂CoᵥO₂₊ᵥ]ₚ[CoO₂], [(Li_{0.5}Ca_{0.5})₂CoᵥO₂₊ᵥ]ₚ[CoO₂], [(Na_{0.5}Ca_{0.5})₂CoᵥO₂₊ᵥ]ₚ[CoO₂], [(K_{0.5}Ca_{0.5})₂CoᵥO₂₊ᵥ]ₚ[CoO₂], [Li₂NiᵥO₂₊ᵥ]ₚ[CoO₂], [Mg₂NiᵥO₂₊ᵥ]ₚ[CoO₂], [Ca₂CuᵥO₂₊ᵥ]ₚ[CoO₂], [Sr₂CuᵥO₂₊ᵥ]ₚ[CoO₂], [(Mg_{0.5}Ca_{0.5})₂CuᵥO₂₊ᵥ]ₚ[CoO₂], [(Ca_{0.5}Sr_{0.5})₂CuᵥO₂₊ᵥ]ₚ[CoO₂], [(Li_{0.5}Sr_{0.5})₂CuᵥO₂₊ᵥ]ₚ[CoO₂], [Ca₂ZnᵥO₂₊ᵥ]ₚ[CoO₂], [Ca₂NbᵥO₂₊ᵥ]ₚ[CoO₂], [Ca₂CdᵥO₂₊ᵥ]ₚ[CoO₂], [Ca₂WᵥO₂₊ᵥ]ₚ[CoO₂], and [Ca₂IrᵥO₂₊ᵥ]ₚ[CoO₂].

In another embodiment, M in formula (3) represents a combination of transition metals, and more preferably, a combination of first row transition metals. Some examples of classes of such compositions include [Li₂(Co_{0.5}Tl_{0.5})ᵥO₂₊ᵥ]ₚ[CoO₂], [Li₂(Co_{0.2}V_{0.8})ᵥO₂₊ᵥ]ₚ[CoO₂], [Na₂(Co_{0.5}Cr_{0.5})ᵥO₁₊ᵥ]ₚ[CoO₂], [(Li_{0.5}Na_{0.5})₂(Co_{0.5}Mn_{0.5})ᵥO₂₊ᵥ]ₚ[CoO₂], [Mg₂(Co_{0.4}Fe_{0.6})ᵥO₂₊ᵥ]ₚ[CoO₂], [Ca₂(Co_{0.5}Cu_{0.5})ᵥO₂₊ᵥ]ₚ[CoO₂], [Ca₂(Co_{0.8}Cu_{0.2})ᵥO₂₊ᵥ]ₚ[CoO₂], [Sr₂(Co_{0.5}Cu_{0.5})ᵥO₂₊ᵥ]ₚ[CoO₂], [(Mg_{0.5}Ca_{0.5})₂(Co_{0.5}Cu_{0.5})ᵥO₂₊ᵥ]ₚ[CoO₂], [(Ca_{0.5}Sr_{0.5})₂(Co_{0.5}Cu_{0.5})ᵥO₂₊ᵥ]ₚ[CoO₂], [(Ca_{0.8}Sr_{0.2})₂(Co_{0.5}Ni_{0.5})ᵥO₂₊ᵥ]ₚ[CoO₂], [(Li_{0.5}Sr_{0.5})₂(Co_{0.5}Zn_{0.5})ᵥO₂₊ᵥ]ₚ[CoO₂], [Li₂(Co_{0.5}W_{0.5})ᵥO₂₊ᵥ]ₚ[CoO₂], [Na₂(Co_{0.7}Zr_{0.3})ᵥO₂₊ᵥ]ₚ[CoO₂], [Li₂(Co_{0.5}Rh_{0.5})ᵥO₂₊ᵥ]ₚ[CoO₂], [(Li_{0.4}Na_{0.6})₂(Co_{0.5}Rh_{0.5})ᵥO₂₊ᵥ]ₚ[CoO₂], [Li₂(Co_{0.5}Ir_{0.5})ᵥO₂₊ᵥ]ₚ[CoO₂], [Ca₂(Co_{0.6}Re_{0.4})ᵥO₂₊ᵥ]ₚ[CoO₂], [Ca₂(Co_{0.6}Cu_{0.2}Mn_{0.2})ᵥO₂₊ᵥ]ₚ[CoO₂], [Ca₂(Co_{0.6}Ni_{0.2}Cu_{0.2})ᵥO₂₊ᵥ]ₚ[CoO₂], [(Ca_{0.5}Sr_{0.5})₂(Co_{0.6}Ni_{0.2}Cu_{0.2})ᵥO₂₊ᵥ]ₚ[CoO₂], [(Na_{0.5}Sr_{0.5})₂(Co_{0.6}Ni_{0.2}Cu_{0.1}Zn_{0.1})ᵥO₂₊ᵥ]ₚ[CoO₂], [Li₂(V_{0.5}Ti_{0.5})ᵥO₂₊ᵥ]ₚ[CoO₂], [Li₂(Cr_{0.2}V_{0.8})ᵥO₂₊ᵥ]ₚ[CoO₂], [Li₂(Ni_{0.5}Ti_{0.5})ᵥO₂₊ᵥ]ₚ[CoO₂], [Na₂(Zn_{0.5}V_{0.5})ᵥO₂₊ᵥ]ₚ[CoO₂], [(Li_{0.5}Na_{0.5})₂(Zr_{0.5}Ta_{0.5})ᵥO₂₊ᵥ]ₚ[CoO₂], [Mg₂(Ni_{0.5}Ta_{0.5})ᵥO₂₊ᵥ]ₚ[CoO₂], and [Li₂(Ni_{0.5}Cd_{0.5})ᵥO₂₊ᵥ]ₚ[CoO₂].

In another embodiment, M in formula (3) represents one or more transition metals in combination with one or more main group metals. Some examples of classes of such compositions include [Li₂(Co_{0.6}Tl_{0.4})ᵥO₂₊ᵥ]ₚ[CoO₂], [Na₂(Co_{0.6}Tl_{0.4})ᵥO₂₊ᵥ]ₚ[CoO₂], [(Li_{0.5}Na_{0.5})₂(Co_{0.5}Tl_{0.5})ᵥO₂₊ᵥ]ₚ[CoO₂], [Ca₂(Co_{0.5}Tl_{0.5})ᵥO₂₊ᵥ]ₚ[CoO₂], [Sr₂(Co_{0.2}Tl_{0.8})ᵥO₂₊ᵥ]ₚ[CoO₂], [(Ca_{0.5}Sr_{0.5})₂(C_{0.6}Tl_{0.4})ᵥO₂₊ᵥ]ₚ[CoO₂], [(Na_{0.5}Sr_{0.5})₂(Co_{0.8}Tl_{0.2})ᵥO₁₊ᵥ]ₚ[CoO₂], [Li₂(Co_{0.6}Bi_{0.4})ᵥO₂₊ᵥ]ₚ[CoO₂], [Na₂(Co_{0.6}Bi_{0.4})ᵥO₂₊ᵥ]ₚ[CoO₂], [(Li_{0.5}Na_{0.5})₂(Co_{0.5}Bi_{0.5})ᵥO₂₊ᵥ]ₚ[CoO₂], [Ca₂(Co_{0.5}In_{0.5})ᵥO₂₊ᵥ]ₚ[CoO₂], [Sr₂(Co_{0.2}In_{0.8})ᵥO₂₊ᵥ]ₚ[CoO₂], [(Ca_{0.5}Sr_{0.5})₂(Co_{0.6}In_{0.4})ᵥO₂₊ᵥ]ₚ[CoO₂], [Ca₂(Co_{0.5}Bi_{0.25}In_{0.25})ᵥO₂₊ᵥ]ₚ[CoO₂], [(Ca_{0.5}Sr_{0.5})₂(Co_{0.5}Bi_{0.25}In_{0.25})ᵥO₂₊ᵥ]ₚ[CoO₂], [Ca₂(Co_{0.6}Cr_{0.2}Tl_{0.2})ᵥO₂₊ᵥ]ₚ[CoO₂], [Ca₂(Co_{0.6}Cu_{0.2}Tl_{0.2})ᵥO₂₊ᵥ]ₚ[CoO₂], [Ca₂(Co_{0.6}Cu_{0.2}Bi_{0.2})ᵥO₂₊ᵥ]ₚ[CoO₂], [Ca₂(Co_{0.6}Cu_{0.2}Tl_{0.1}Bi_{0.1})ᵥO₂₊ᵥ]ₚ[CoO₂], [Ca₂(Cu_{0.6}Tl_{0.4})ᵥO₂₊ᵥ]ₚ[CoO₂], [Ca₂(Cu_{0.6}Bi_{0.4})ᵥO₂₊ᵥ]ₚ[CoO₂], and [Ca₂(Ni_{0.6}Bi_{0.4})ᵥO₂₊ᵥ]ₚ[CoO₂].

In another embodiment, M in formula (3) represents one or a combination of rare earth metals, or one or more rare earth metals in combination with one or more other metals. Some examples of classes of such compositions include [Li₂LaᵥO₂₊ᵥ]ₚ[CoO₂], [Ca₂LaᵥO₂₊ᵥ]ₚ[CoO₂], [Na₂CeᵥO₂₊ᵥ]ₚ[CoO₂], [(Li_{0.5}Na_{0.5})₂CeᵥO₂₊ᵥ]ₚ[CoO₂], [Ca₂CeᵥO₂₊ᵥ]ₚ[CoO₂], [Li₂NdᵥO₂₊ᵥ]ₚ[CoO₂], [Ca₂NdᵥO₂₊ᵥ]ₚ[CoO₂], [Ca₂(La_{0.6}Ce_{0.4})ᵥO₂₊ᵥ]ₚ[CoO₂], [Ca₂(Ce_{0.5}Nd_{0.5})ᵥO₂₊ᵥ]ₚ[CoO₂], [(Ca_{0.5}Sr_{0.5})₂EuᵥO₂₊ᵥ]ₚ[CoO₂] [(Ca_{0.5}Sr_{0.5})₂(Eu_{0.5}Nd_{0.5})ᵥO₂₊ᵥ]ₚ[CoO₂], [Ca₂GdᵥO₂₊ᵥ]ₚ[CoO₂], and [Ca₂(Eu_{0.5}Gd_{0.5})ᵥO₂₊ᵥ]ₚ[CoO₂], [Ca₂(Ce_{0.5}Co_{0.5})ᵥO₂₊ᵥ]ₚ[CoO₂], [Ca₂(La_{0.5}Co_{0.5})ᵥO₂₊ᵥ]ₚ[CoO₂], [Ca₂(Gd_{0.5}Cu_{0.5})ᵥO₂₊ᵥ]ₚ[CoO₂], [(Ca_{0.5}Mg_{0.5})₂(Eu_{0.5}Ni_{0.5})ᵥO₂₊ᵥ]ₚ[CoO₂], [Li₂(Sm_{0.5}Tl_{0.5})ᵥO₂₊ᵥ]ₚ[CoO₂], [Na_{0.4}Ca_{0.5})₂(Ce_{0.5}Bi_{0.5})ᵥO₂₊ᵥ]ₚ[CoO₂], [Li₂(Sm_{0.9}Bi_{0.1})ᵥO₂₊ᵥ]ₚ[CoO₂], and [Ca₂(Co_{0.6}Gd_{0.2}Bi_{0.2})ᵥO₂₊ᵥ]ₚ[CoO₂].

In another embodiment of formula (3), y is not zero, thereby including substituting metals T. Some examples of such compositions include [Li₂TlᵥO₂₊ᵥ]ₚ[Co_{0.5}Ni_{0.5}O₂], [Na₂TlᵥO₂₊ᵥ]ₚ[Co_{0.5}Cu_{0.5}O₂], [(Li_{0.5}Na_{0.5})₂TlᵥO₂₊ᵥ]ₚ[Co_{0.5}Cu_{0.5}O₂], [Mg₂(Bi_{0.5}Tl_{0.5})ᵥO₂₊ᵥ]ₚ[Co_{0.5}Bi_{0.5}O₂], [Ca₂(Bi_{0.5}Tl_{0.5})ᵥO₂₊ᵥ]ₚ[Co_{0.8}Mn_{0.2}O₂], [Sr₂(Bi_{0.5}Tl_{0.5})ᵥO₂₊ᵥ]ₚ[Co_{0.5}Cu_{0.5}O₂], [(Mg_{0.5}Ca_{0.5})₂(Bi_{0.5}Tl_{0.5})ᵥO₂₊ᵥ]ₚ[Co_{0.5}Cu_{0.5}O₂], [Ca₂CoᵥO₂₊ᵥ]ₚ[Co_{0.5}Cu_{0.5}O₂], [Sr₂CoᵥO₁₊ᵥ]ₚ[Co_{0.5}Cu_{0.5}O₂], [(Mg_{0.5}Ca_{0.5})₂CoᵥO₂₊ᵥ]ₚ[Co_{0.5}Ce_{0.5}O₂], [Ca₂CuᵥO₂₊ᵥ]ₚ[Co_{0.8}Cd_{0.2}O₂], [Sr₂CuᵥO₂₊ᵥ]ₚ[Co_{0.5}Cu_{0.5}O₂], [Li₂(Co_{0.5}Ti_{0.5})ᵥO₂₊ᵥ]ₚ[Co_{0.5}Ni_{0.5}O₂], [Li₂(Co_{0.2}V_{0.8})ᵥO₂₊ᵥ]ₚ[Co_{0.4}Rh_{0.6}O₂], [Na₂(Co_{0.5}Cr_{0.5})ᵥO₂₊ᵥ]ₚ[Co_{0.5}Cu_{0.5}O₂], [(Li_{0.5}Na_{0.5})₂(Co_{0.5}Mn_{0.5})ᵥO₂₊ᵥ]ₚ[Co_{0.8}Cu_{0.2}O₂], [Mg₂CoᵥO₂₊ᵥ]ₚ[Co_{0.2}Mn_{0.8}O₂], [Ca₂(Co_{0.5}Cu_{0.5})ᵥO₂₊ᵥ]ₚ[Co_{0.5}Ni_{0.5}O₂], [Ca₂(Co_{0.5}In_{0.5})ᵥO₂₊ᵥ]ₚ[Co_{0.2}Cu_{0.8}O₂], [Sr₂(Co_{0.2}In_{0.8})ᵥO₂₊ᵥ]ₚ[Co_{0.8}Cu_{0.2}O₂], [(Ca_{0.5}Sr_{0.5})₂(Co_{0.6}In_{0.4})ᵥO₂₊ᵥ]ₚ[Co_{0.9}Cu_{0.1}O₂], [Ca₂CoᵥO₂₊ᵥ]ₚ[Co_{0.1}Cu_{0.9}O₂], [Li₂LaᵥO₂₊ᵥ]ₚ[Co_{0.5}Cu_{0.5}O₂], and [Ca_{2.7}Sr_{0.2}La_{0.1}][Co_{3.9}Cu_{0.1}]O₉.

In a preferred embodiment of formula (3), the cobalt oxide composition of the thermoelectric film is represented by the formula
[Ca₂CoᵥO₂₊ᵥ]ₚ[CoO₂] (4)

In formula (4), the symbols p and v are as described above. More preferably, v is approximately 1 and p is in the range of approximately 0.6 to 0.7 in formula (4).

Even more preferably, p in formula (4) is approximately 0.62. When p is approximately 0.62 and v is approximately 1, the cobalt oxide composition can be denoted as [Ca₂CoO₃]_{0.62}[CoO₂], which corresponds approximately to the empirical formula Ca₃Co₄O₉ (i.e., “Co349”). See Y. Miyazaki, Solid State Ionics, 172, pp. 463-467 (2004), which is incorporated herein by reference.

The cobalt oxide film has any suitable thermoelectric properties. In a preferred embodiment, the cobalt oxide film has a resistivity of or less than 5 mOhm.cm and a power rating of or greater than 100 μV/K² at 300 K. Such a cobalt oxide film has a minimum power rating of about 2 μW/cm.K² at 300 K.

More preferably, the cobalt oxide film has any suitable combination of resistivity and power rating which results in a power factor of greater than 16 μW/cm.K² at 300 K. Some examples of preferred resistivities and power ratings at 300 K are provided in Table 1 below.

TABLE 1

| Resistivity (ρ) in | Power Rating (S) | Power Factor (P.F.) in |
|---|---|---|
| mOhm · cm | in μV/K² | μW/cm · K² (S²/ρ × 10⁻³) |
| 100 | 0.6 | 16.7 |
| 100 | 0.4 | 25.0 |
| 100 | 0.3 | 33.3 |
| 120 | 0.8 | 18.0 |
| 120 | 0.5 | 28.8 |
| 130 | 1.0 | 16.9 |
| 130 | 0.5 | 33.8 |
| 150 | 1.4 | 16.1 |
| 150 | 1.0 | 22.5 |
| 150 | 0.5 | 45.0 |
| 160 | 1.5 | 17.1 |
| 180 | 2.0 | 16.2 |
| 180 | 1.0 | 32.4 |

The thermoelectric cobalt oxide film can have any suitable thickness. For example, the cobalt oxide film can have a thickness of, or less than, approximately several hundred microns, one hundred microns (100 μm), fifty microns (50 μm), twenty microns (20 μm), or one micron (1 μm).

More preferably, the cobalt oxide film has a thickness of, or less than, approximately 500 nm (5,000 Å). For example, the cobalt oxide film can have an average thickness of, for example, 450 nm, 400 nm, 350 nm, 300 nm, 250 nm, 230 nm, 200 nm, 180 nm, 150 nm, 120 nm, 100 nm, 75 nm, 50 nm, 25 nm, 15 nm, 10 nm, 5 nm, or less.

The cobalt oxide film can have any suitable physical characteristics. For example, the cobalt oxide film can be epitaxial or non-epitaxial. The cobalt oxide film can also be crystalline or non-crystalline, i.e., amorphous. Some types of suitable crystalline films include single crystalline and non-single crystalline forms. Non-single crystalline films include, for example, polycrystalline films. Non-single crystalline films also include films having one or a combination of randomly oriented axes or planes, e.g., randomly oriented ab-planes.

The cobalt oxide film is preferably on a suitable substrate. The substrate can be any desired substrate for which such a thermoelectric film of cobalt oxide can be deposited. For example, the substrate can be a metal, metal alloy, ceramic, plastic, or organic, inorganic, or organic-inorganic hybrid polymer.

Preferably, the substrate includes one or a combination of metals. Some examples of classes of suitable metals for the substrate include the alkaline earth, transition, main group, and rare earth classes of metals. These classes of metals have been described above.

The metals can be in their zerovalent oxidation states (i.e., elemental forms) or in their non-zerovalent oxidation states. Elemental forms include single metals, metal alloys, and laminates thereof. Non-zerovalent metal compositions include non-zerovalent metal compounds and materials (e.g., metal salts).

In a preferred embodiment, the substrate includes one or a combination of main group metals. For example, the substrate can be composed of one or a combination of main group metals in their elemental states (e.g., Al, Sn, Si, Al—Cu, Al—Fe, and so on), or in their non-zerovalent oxidation states (e.g., Al₂O₃, SnO₂, SiO₂, In₂O₃, In₂O₃/SnO₂).

The substrate can include one or more main group elements in combination with one or more alkaline earth, transition, or rare earth metals. For example, the substrate can be in the form of a metal boride, metal aluminide, metal gallide, metal indide, metal carbide, metal silicide, metal germanide, metal stannide, metal oxide, metal sulfide, metal selenide, metal telluride, metal nitride, metal phosphide, metal arsenide, metal antimonide, and combinations thereof.

Some examples of classes of metal oxides suitable as substrates include the class of aluminum oxides (e.g., the class of micas and sapphires), silicon oxides, titanium oxides, vanadium oxides, chromium oxides, manganese oxides, iron oxides, cobalt oxides, nickel oxides, copper oxides, yttrium oxides, zirconium oxides, niobium oxides, molybdenum oxides, ruthenium oxides, tantalum oxides, tungsten oxides, rhenium oxides, gallium oxides, indium oxides, tin oxides, indium tin oxides, germanium oxides, thallium oxides, lithium oxides, magnesium oxides, and calcium oxides.

Some examples of classes of metal sulfides suitable as substrates include the class of cadmium sulfides, gallium sulfides, iron sulfides, nickel sulfides, copper sulfides, lead sulfides, and zinc sulfides. Some examples of classes of metal selenides suitable as substrates include the class of cadmium selenides, gallium selenides, copper selenides, and zinc selenides. Some examples of classes of metal tellurides suitable as substrates include the class of cadmium tellurides, antimony tellurides, arsenic tellurides, bismuth tellurides, copper tellurides, europium tellurides, gallium tellurides, manganese tellurides, lead tellurides, and zinc tellurides.

Some examples of classes of metal nitrides suitable as substrates include the class of gallium nitrides, indium nitrides, aluminum nitrides, and boron nitrides. Some examples of classes of metal phosphides suitable as substrates include the class of gallium phosphides, indium phosphides, and zinc phosphides. Some examples of classes of metal arsenides suitable as substrates include the class of gallium arsenides, indium arsenides, and zinc arsenides.

Some examples of classes of metal borides suitable as substrates include the class of vanadium borides, barium borides, calcium borides, chromium borides, cobalt borides, hafnium borides, lanthanum borides, magnesium borides, molybdenum borides, nickel borides, tantalum borides, titanium borides, and zirconium borides.

Some examples of classes of metal carbides suitable as substrates include the class of titanium carbides, vanadium carbides, chromium carbides, manganese carbides, iron carbides, cobalt carbides, nickel carbides, copper carbides, zinc carbides, niobium carbides, tantalum carbides, molybdenum carbides, tungsten carbides, silicon carbides, aluminum carbides, boron carbides, lithium carbides, barium carbides, calcium carbides, and cerium carbides.

Some examples of classes of metal suicides suitable as metal surfaces include the class of titanium suicides, vanadium silicides, chromium suicides, manganese silicides, iron silicides, cobalt silicides, nickel silicides, copper suicides, zirconium silicides, niobium silicides, molybdenum silicides, hafnium suicides, tantalum suicides, tungsten silicides, rhenium silicides, lanthanum suicides, cerium suicides, neodymium silicides, gadolinium silicides, ytterbium silicides, uranium silicides, boron silicides, beryllium suicides, magnesium suicides, calcium silicides, and aluminum suicides.

The substrate can also be a superconducting metal or metal alloy. For example, the substrate can be in the class of copper oxide superconducting materials. Some examples of copper oxide superconducting materials include the yttrium barium copper oxides (YBCO), lanthanum strontium copper oxides (LSCO), and magnesium boride classes of superconductors.

In another embodiment, the substrate includes one or a combination of metal salt compounds. The metal salt compounds include one or more metal atoms associated with one or more anions. The anions can be singly negatively charged, doubly negatively charged, triply negatively charged, and more highly charged. Some examples of suitable anions include fluoride, chloride, bromide, iodide, sulfate, methanesulfonate, trifluoromethanesulfonate, sulfite, nitrate, nitrite, phosphate, arsenate, phosphite, hypophosphite, carbonate, chlorate, perchlorate, iodate, oxalate, acetate, borate, metaborate, tetraborate, tungstate, molybdate, silicate, orthosilicate, titanate, cobaltate, vanadate, zirconate, niobate, chromate, and cuprate.

Some examples of metal salt compounds suitable as substrates include lithium flouride, lithium chloride, lithium nitrate, lithium periodate, lithium tetrachlorocuprate, sodium chloride, sodium fluoride, sodium nitrate, sodium carbonate, sodium hexafluoroaresenate, potassium fluoride, potassium niobate, potassium iodate, calcium carbonate, calcium tungstate, calcium zirconate, calcium arsenate, calcium iodate, beryllium fluoride, magnesium acetate, magnesium carbonate, magnesium chloride, magnesium fluoride, magnesium bromide, magnesium nitrate, magnesium salicylate, magnesium silicate, magnesium sulfate, magnesium titanate, magnesium tungstate, strontium fluoride, strontium bromide, strontium carbonate, strontium oxalate, strontium titanate, strontium zirconate, barium zirconate, zirconium fluoride, aluminum titanate, iron titanate, nickel carbonate, lead zirconate, lead arsenate, manganese zirconate, aluminum perchlorate, barium perchlorate, cerium perchlorate, bismuth titanate, ammonium fluoride, ammonium nitrate, ammonium tetrafluoroborate, and ammonium hexafluorotitanate.

In another embodiment, the substrate is a combination of any of the metals and metal compounds described above. For example, the substrate can be a combination of silicon and silicon nitride; silicon and silicon oxide; aluminum oxide and silicon oxide; aluminum oxide and zirconia; yttria and zirconia; or zirconium fluoride and indium tin oxide.

In a particularly preferred embodiment, the substrate contains one or more silicon-group metals, i.e., metals selected from the Group IVA class of metals. Some examples of Group IVA metals include silicon and germanium. The substrates can be doped or undoped (e.g., n-doped or p-doped) and have any suitable level of resistivity. The substrates can also be electrically conductive, semiconductive, or non-conductive.

As noted earlier, the silicon-group metals are particularly advantageous as substrates for the cobalt oxide films since such substrates are widely used in the electronics, semiconductor, and other advanced technology industries. Accordingly, depositing the thermoelectric cobalt oxide films onto such substrates allows these cobalt oxide films to be integrated into a variety of advanced devices.

For example, the substrate can include an oxide, sulfide, selenide, telluride, nitride, phosphide, arsenide, antimonide, carbide, germanide, stannide, boride, aluminide, gallide, indide, or halide, of silicon; or an oxide, sulfide, selenide, telluride, nitride, phosphide, arsenide, antimonide, carbide, silicide, stannide, boride, aluminide, gallide, indide, or halide, of germanium; or a combination thereof.

In other preferred embodiments, the substrate includes zerovalent silicon, silicon oxide, zerovalent silicon having a silicon oxide surface, or glass. These silicon-containing substrates can be undoped, or alternatively, doped with any one or combination of suitable dopants, such as, for example, boron, phosphorus, or arsenic.

The substrate can have any suitable physical characteristics. For example, the substrate can be crystalline or non-crystalline. Some types of crystalline substrates include single crystalline and non-single crystalline substrates. Non-single crystalline substrates include, for example, polycrystalline substrates (e.g., polycrystalline Al₂O₃).

The composition and physical characteristics of the substrate, including its crystalline character, can affect the thermoelectric properties and performance of the cobalt oxide film. In this regard, modification of, or improvement of, thermoelectric properties of the cobalt oxide film by use of specific types of substrates is within the scope of the present invention. For example, it has been shown by the present inventors that, at least in certain instances, use of a polycrystalline substrate can improve the thermoelectric properties of the cobalt oxide film.

In another aspect, the invention relates to thermal management and thermoelectric generator devices containing the cobalt oxide films described above. The thermoelectric component of the device includes the cobalt oxide film, either as a monolithic film (i.e., in the absence of a substrate), or as a film on a suitable substrate. In the device, the cobalt oxide film is preferably fitted with electrically conductive contacts.

The thermoelectric device also includes any desirable housing and/or additional or auxiliary components. For example, the device can include appropriate sensors, actuators, electronic chips, circuitry, electrical power sources, electrical storage components, and the like.

In another aspect, the invention relates to methods for altering the thermal characteristics of a device. The method is particularly directed to thermal management of devices, such as electronic chips, requiring such management.

The method uses a thermoelectric component which includes a suitable cobalt oxide film, as described above. The thermoelectric component can be the film itself, the film on a suitable substrate, or the foregoing along with any additional suitable components, i.e., additional coatings, housings, wiring, etc.

In the thermal management method, a suitable electrical current is supplied to the cobalt oxide film (i.e., the thermoelectric component). A suitable electrical current is one which is capable of producing a suitable thermal response in the cobalt oxide film. The current can be applied in a mode which allows the cobalt oxide film to cool a device, or conversely, to heat a device.

The thermal management method requires a mode of heat transfer between the thermoelectric component and the device requiring thermal management. The mode of heat transfer can be any suitable mode which allows for the transfer of heat.

Heat transfer can be achieved by direct or indirect thermal contact between the thermoelectric component and the device. In direct thermal contact, there is a physical connection between the thermoelectric component and the device. In indirect thermal contact, there is no physical connection between the thermoelectric component and the device. For example, indirect thermal contact can be achieved by having a space (e.g., a gas or vacuum), a thermal conductor, or a combination thereof, between the thermoelectric component and the device.

In another aspect, the invention relates to methods for generating electrical energy from a heat source. The method uses a thermoelectric component containing a suitable cobalt oxide film, as described above, to convert thermal energy to electrical energy.

The heat source can be any suitable heat source. Preferably, the heat source is a source of waste heat, e.g., waste heat from a combustion engine, a fuel cell, or nuclear fuel. The heat can also be generated by, for example, solar irradiation or geothermal sources.

The method for generating electrical energy requires a mode of heat transfer between the thermoelectric component and the heat source. Suitable modes of heat transfer have been described above.

In a preferred embodiment, the method for generating electrical energy includes an electrical power receiver which is in electrical contact with the thermoelectric component. The electrical power receiver is preferably capable of using or storing the electrical energy generated from the thermoelectric component.

The electrical power receiver can use the generated electrical energy for any suitable purpose including, for example, lighting, operation of a mechanical device, and generation of magnetism. The electrical power receiver can store the generated electrical energy by any suitable method, including by use of, for example, any suitable one or combination of capacitors. The stored electrical energy can be subsequently used for any of a variety of purposes.

In another aspect, the invention relates to methods for growing any of a variety of metal oxide films on silicon-group substrates. In the method, a metal oxide film is deposited onto a silicon-group substrate coated (i.e., pre-coated) with a suitable cobalt oxide film, as described above. The cobalt oxide film functions as a buffer oxide (i.e., intermediate oxide) layer which makes deposition of another metal oxide film more facile.

The deposited metal oxide film can be any suitable metal oxide, including an oxide of one or a combination of metals selected from the alkali, alkaline earth, main group, transition, and rare earth metals. Some examples of particularly relevant metal oxide films include LiNiO₂, TiO₂, and ErFe₂O₄.

Silicon-group substrates, particularly, silicon and silicon oxide, are typically not amenable for the direct deposition of metal oxides. Growth of oxide films on such substrates presents significant challenges due to chemical, thermal, and lattice-matching incompatibilities. Therefore, the foregoing deposition method is particularly advantageous in that a wide range of metal oxide films can be deposited which typically could not be deposited, or which would require more difficult means to do so.

The thermoelectric cobalt oxide films described above can be produced by any suitable method. Some methods known in the art include chemical vapor deposition (CVD), plasma vapor deposition (PVD), laser deposition techniques, and sol gel techniques.

In a preferred embodiment, the cobalt oxide films are produced using pulsed laser deposition (PLD) techniques. In PLD, a plasma is produced from a precursor material by subjecting the precursor material to a high energy laser beam of a suitable wavelength, energy density, and repetition rate (i.e., frequency). The resulting plasma is condensed onto the substrate while maintaining the substrate under suitable conditions, for example, in a suitable temperature range, atmospheric composition, and pressure.

For example, in preferred embodiments, cobalt oxide films can be deposited using the PLD technique with the following parameters: a laser (e.g., a KrF excimer laser) with a wavelength of approximately 248 nm; an energy density in the range of approximately 1.5-2.5 J/cm²; a repetition rate in the range of approximately 2-10 Hz; an oxygen atmosphere having a pressure in the range of approximately 50-500 mTorr (i.e., 0.066-0.66 mbar or 6.67-66.7 Pa); and a temperature range of approximately 600-800° C., and more preferably 680-700° C.

In a further embodiment, the method for depositing cobalt oxide films includes cooling the substrate at a suitable cooling rate. The cooling rate can be any suitable cooling rate. For example, the cooling rate can be anywhere in the range of approximately 120° C./min to 1° C./min. More preferably, the cooling rate is in the range of approximately 100° C./min to 20° C./min. Some examples of more preferred cooling rates include 90° C./min, 80° C./min, 70° C./min, 60° C./min, 50° C./min, 40° C./min, and 30° C./min.

For obtaining cobalt oxide films having high power factors, e.g., greater than approximately 16 μW/cmK² at 300 K, the PLD technique is preferably operated as above with an energy density of approximately 2.0 J/cm²; a repetition rate of approximately 5 Hz; an oxygen atmosphere having a pressure of approximately 300 mTorr, a temperature of approximately 680° C., and a cooling rate of approximately 60° C./min.

Examples have been set forth below for the purpose of illustration and to describe the best mode of the invention at the present time. However, the scope of this invention is not to be in any way limited by the examples set forth herein.

### EXAMPLE 1

### Preparation of Ca₃Co₄O₉ Films on Silicon Substrate

Our Ca₃Co₄O₉ thin films were grown in situ by the PLD process. The Ca₃Co₄O₉ target was prepared from high-purity CaCO₃ and Co₃O₄ powders. The stoichiometrically mixed powders were calcined two times at 880-890° C. for 24 hours in flowing air with intermediate grinding, and then pressed into a disk for final sintering at 900° C. for 24 hours in flowing O₂ gas.

Single-crystal Si (100) (commercial wafer) were cleaned in acetone and methanol prior to the deposition, but not chemically treated to remove the native oxide layer on the Si substrate surface. Films about 2300 Å thick were deposited at a substrate temperature of 700° C. with a laser energy density of ˜1.5 J/cm², under an oxygen pressure of 300 mTorr. After deposition, films were cooled to room temperature in ˜1 atmosphere of oxygen.

### EXAMPLE 2

### Characterization of Ca₃Co₄O₉ Films on Silicon Substrate

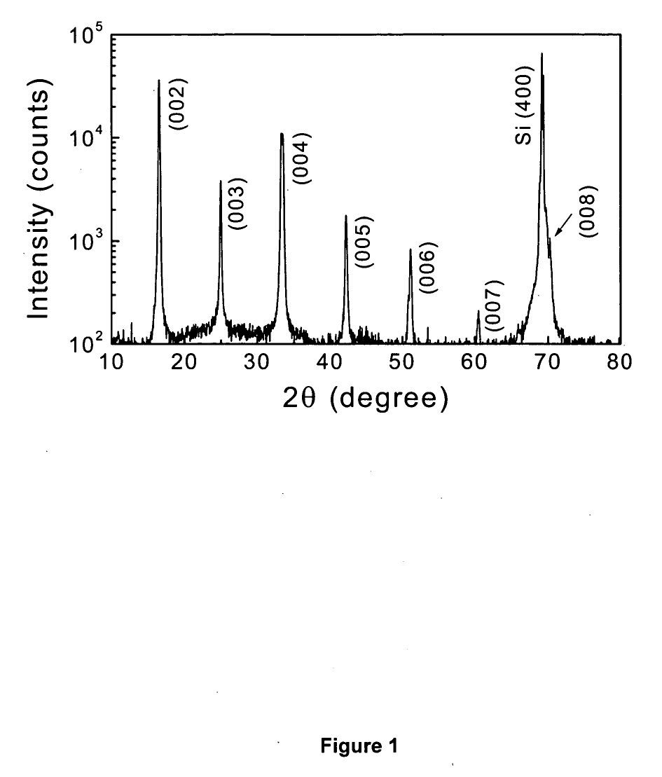

FIG. 1 shows the x-ray diffraction (XRD) patterns for the Ca₃Co₄O₉ film grown on single crystalline Si (100) substrate. The XRD patterns exhibit nearly perfect c-axis alignment for the thin film (note: the log-scale used for counts). No diffraction peaks due to impurity phases were observed.

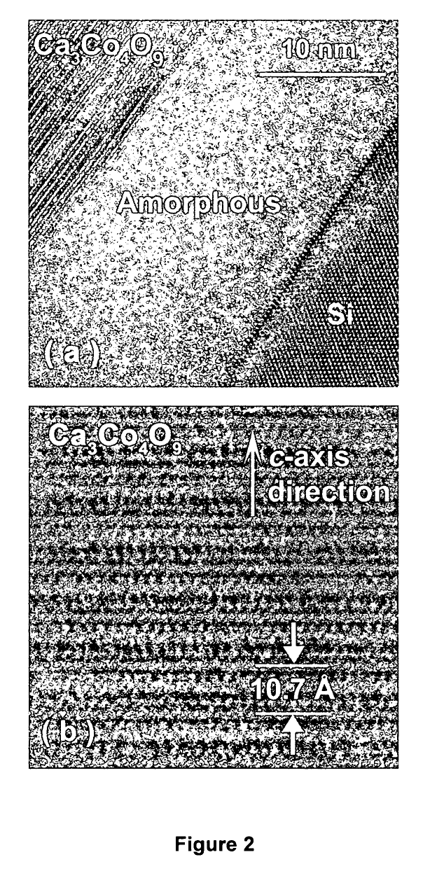

Cross-sectional transmission electron microscopy (TEM) images of a Ca₃Co₄O₉ film on Si (100) substrate are shown in FIG. 2. FIG. 2(a) is the high-resolution electron microscopy (HREM) overview image of the Ca₃Co₄O₉/Si interface region, where the atomic Ca₃Co₄O₉ layered structure and single-crystal Si structure can be seen. Between the Ca₃Co₄O₉ film and Si substrate, there is an amorphous layer with a thickness of ˜20 nm. An extensive TEM investigation along the interface at various locations suggests that there are two distinct regions in the amorphous layer. The region adjacent to the Si substrate (˜5 nm thick) is likely the SiOₓ amorphous layer, while the region adjacent to the Ca₃Co₄O₉ film is a predominantly amorphous material containing some nanoscaled crystalline domains related to Ca₃Co₄O₉.

FIG. 2(b) shows well ordered layer structures of Ca₃Co₄O₉ stacked along the c axis. These structures were invariably observed near the interface and deep inside the Ca₃Co₄O₉ films. No intergrowth defects were detected. The periodicity of the CoO₂ layers was estimated to be 10.7 Å, consistent with the c-axis lattice parameter of Ca₃CoO₉ determined from XRD pattern, as well as the reported value of 10.833 Å for the single-crystal sample.

The growth mechanism of these c-axis-oriented Ca₃Co₄O₉ films on Si is of interest. Note that Si (100) substrate has a cubic structure with the lattice parameter a=5.429 Å, which is hardly a match for the Ca₃Co₄O₉ lattice. Ca₃Co₄O₉ consists of alternating layers of the triple rocksalt-type [Ca₂CoO₃] subsystem (in-plane lattice parameters: a≈4.8 Å, b≈4.5 Å) and the single CdI₂-type [CoO₂] subsystem (in-plane lattice parameters: a≈4.8 Å, b≈2.8 Å) stacked along the c axis. In addition, there is also a thin layer (a few nanometers) of native SiOₓ amorphous layer on the surface of the Si substrate prior to the thin-film deposition. Clearly, we should not expect epitaxial growth of Ca₃Co₄O₉ on Si. The fact that such well ordered Ca₃Co₄O₉ films do form on top of the SiOₓ amorphous layer is perhaps a consequence of a propensity for the cobaltates to self-assemble. In fact, Ca₃Co₄O₉ itself can be considered a self-assembled nanocomposite of stacked misfit layers.

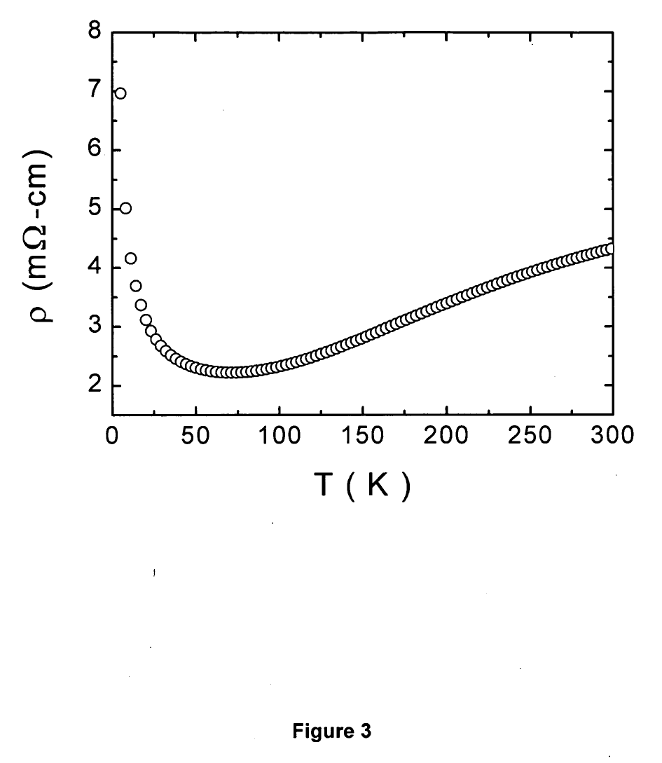

FIG. 3 shows the temperature dependence of the resistivity ρ for Ca₃Co₄O₉ films grown on Si (100) substrate. The film shows a metallic behavior as T decreases from 300 to 70 K. The value of ρ at 300 K is 4.3 mΩ cm for the film with thickness of 2300 Å. This temperature dependence is very similar to that for the Ca₃Co₄O₉ single-crystal in-plane resistivity ρ_{ab}(T). The fact that the resistivity of the Ca₃Co₄O₉ films on Si substrates is actually smaller than that of the single crystal (˜10-40 mΩ cm) and other Ca₃Co₄O₉ films (>10 mΩ cm) suggests that these films are of excellent quality.

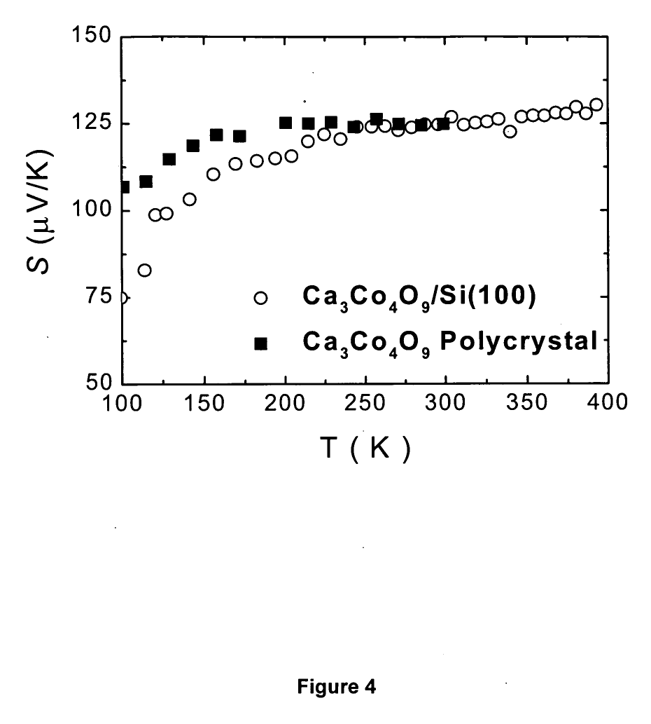

The thermoelectric power of the Ca₃Co₄O₉ films was measured using a four-terminal steady state method in a Quantum Design physical property measurement system. FIG. 4 shows the thermoelectric power as a function of temperature for a Ca₃Co4O₉ film on Si (100) substrate between 100 and 400 K. As a reference, thermoelectric power of a single-phase Ca₃Co₄O₉ polycrystalline sample was also measured and shown in FIG. 4. The contribution of Si substrate to the total thermoelectric power of the film is negligible in this temperature region, which was confirmed by a direct measurement of the thermoelectric power of a bare Si substrate. The thermoelectric power monotonically increases with temperature. At 300 K, the thermoelectric power for the Ca₃Co₄O₉ film on Si (100) and that for the polycrystalline samples are ˜126 μV/K, very close to that of the single-crystal sample (˜125 μV/K). The temperature dependence of thermoelectric power for the Ca₃Co₄O₉ film follows that of the bulk samples, with a slightly lower value at the low-temperature regime. Further improvement on the thermoelectric performance of these films can be made by optimizing deposition conditions.

Significantly, the above results demonstrate that high-quality c-axis-oriented thin films of Ca₃Co₄O₉ can be grown on Si substrates by pulsed-laser deposition without any chemical pretreatment of the substrate surface. The resistivity and thermoelectric power measurements show that these films have superior thermoelectric properties, similar to that found in the bulk samples. This advance suggests that these cobaltates are suitable for incorporation into advanced technology devices.

Thus, whereas there have been described what are presently believed to be the preferred embodiments of the present invention, those skilled in the art will realize that other and further embodiments can be made without departing from the spirit of the invention, and it is intended to include all such further modifications and changes as come within the true scope of the claims set forth herein.

1. A thermoelectric composition comprising a silicon-group substrate coated with a cobalt oxide film having thermoelectric properties.

2. The thermoelectric composition according to claim 1, wherein said cobalt oxide film is single crystalline.

3. The thermoelectric composition according to claim 1, wherein said cobalt oxide film is non-single crystalline.

4. The thermoelectric composition according to claim 3, wherein said cobalt oxide film is polycrystalline.

5. The thermoelectric composition according to claim 3, wherein said cobalt oxide film is amorphous.

6. The thermoelectric composition according to claim 3, wherein said cobalt oxide film has one or a combination of randomly oriented axes or planes.

7. The thermoelectric composition according to claim 1, wherein said substrate is comprised of silicon and/or germanium.

8. The thermoelectric composition according to claim 7, wherein said substrate is comprised of an oxide, sulfide, selenide, telluride, nitride, phosphide, arsenide, antimonide, carbide, germanide, stannide, boride, aluminide, gallide, indide, or halide, of silicon; and/or an oxide, sulfide, selenide, telluride, nitride, phosphide, arsenide, antimonide, carbide, silicide, stannide, boride, aluminide, gallide, indide, or halide, of germanium; or a combination thereof.

9. The thermoelectric composition according to claim 7, wherein said substrate is comprised of zerovalent silicon.

10. The thermoelectric composition according to claim 7, wherein said substrate is comprised of silicon oxide.

11. The thermoelectric composition according to claim 7, wherein said substrate is comprised of zerovalent silicon having a silicon oxide surface.

12. The thermoelectric composition according to claim 1, wherein said cobalt oxide composition is comprised of layers comprising a composition according to the formula Co_{1-y}T_{y}O₂ (1), wherein T represents one or a combination of metal atoms selected from the group consisting of main group, transition and rare earth classes of metals, and y represents 0 or a value greater than 0 and less than 1 for the sum of T.

13. The thermoelectric composition according to claim 12, wherein said cobalt oxide composition is according to the formula AₓCo_{1-y}T_{y}O₂ (2), wherein A represents one or a combination of metal atoms selected from the group consisting of monovalent, divalent, and trivalent metal atoms; T represents one or a combination of metal atoms selected from the group consisting of main group, transition and rare earth classes of metals; x represents a value greater than 0 and less than or equal to approximately 1 for the sum of A; and y represents 0 or a number greater than 0 and less than 1 for the sum of T.

14. The thermoelectric composition according to claim 13, wherein A represents one or a combination of metal atoms selected from the group consisting of alkali and alkaline earth metals.

15. The thermoelectric composition according to claim 14, wherein A represents sodium.

16. The thermoelectric composition according to claim 14, wherein A represents strontium.

17. The thermoelectric composition according to claim 14, wherein A represents calcium.

18. The thermoelectric composition according to claim 14, wherein A represents a combination of sodium and strontium.

19. The thermoelectric composition according to claim 14, wherein A represents a combination of sodium and calcium.

20. The thermoelectric composition according to claim 14, wherein A represents a combination of calcium and strontium.

21. The thermoelectric composition according to claim 12, wherein said cobalt oxide composition is according to the formula [E₂MᵥO₂₊ᵥ]ₚ[Co_{1-y}T_{y}O₂] (3), wherein E represents one or a combination of metal atoms selected from the group consisting of monovalent and divalent metal atoms; M and T independently represent one or a combination of metal atoms selected from the group consisting of main group, transition, and rare earth classes of metals; v represents 0, or a value greater than 0 and less than or equal to 1, or a value greater than 1, for the sum of M; y represents 0 or a value greater than 0 and less than 1 for the sum of T; and p represents a value greater than 0 and less than or equal to 1.

22. The thermoelectric composition according to claim 21, wherein M represents one or a combination of transition metal atoms.

23. The thermoelectric composition according to claim 22, wherein M represents cobalt.

24. The thermoelectric composition according to claim 21, wherein E represents one or a combination of metal atoms selected from the group consisting of alkali and alkaline earth metals.

25. The thermoelectric composition according to claim 24, wherein E represents one or a combination of alkaline earth metal atoms.

26. The thermoelectric composition according to claim 25, wherein E represents calcium.

27. The thermoelectric composition according to claim 26, wherein said layered cobalt oxide composition comprises a composition according to the formula [Ca₂CoᵥO₂₊ᵥ]ₚ[CoO₂] (4), wherein v represents 0, or a value greater than 0 and less than or equal to 1, or a value greater than 1; and p represents a value greater than 0 and less than or equal to 1.

28. The thermoelectric composition according to claim 27, wherein v is approximately 1 and p is in a range of approximately 0.6 to 0.7.

29. The thermoelectric composition according to claim 28, wherein p is approximately 0.62 and said cobalt oxide composition comprises a composition of approximate empirical formula Ca₃Co₄O₉.

30. A thermoelectric composition comprising a silicon-containing substrate coated with a thermoelectric film comprising a composition according to the formula AₓCo_{1-y}T_{y}O₂ (2), wherein A represents one or a combination of metal atoms selected from the group consisting of monovalent, divalent, and trivalent metal atoms; T represents one or a combination of metal atoms selected from the group consisting of main group, transition and rare earth classes of metals; x represents a value greater than 0 and less than or equal to approximately 1 for the sum of A; and y represents 0 or a number greater than 0 and less than 1 for the sum of T.

31. A thermoelectric composition comprising a silicon-containing substrate coated with a thermoelectric film comprising a composition according to the formula AₓCo_{1-y}T_{y}O₂ (2), wherein A represents one or a combination of metal atoms selected from the group consisting of alkali and alkaline earth metal atoms; T represents one or a combination of transition metal atoms; x represents a value greater than 0 and less than or equal to approximately 1 for the sum of A; and y represents 0 or a number greater than 0 and less than 1 for the sum of T.

32. A thermoelectric composition comprising a silicon-containing substrate coated with a thermoelectric film comprising a composition according to the formula [E₂MᵥO₂₊ᵥ]ₚ[Co_{1-y}T_{y}O₂] (3), wherein E represents one or a combination of metal atoms selected from the group consisting of monovalent and divalent metal atoms; M and T independently represent one or a combination of metal atoms selected from the group consisting of main group, transition, and rare earth classes of metals; v represents 0, or a value greater than 0 and less than or equal to 1, or a value greater than 1, for the sum of M; y represents 0 or a value greater than 0 and less than 1 for the sum of T; and p represents a value greater than 0 and less than or equal to 1.

33. A thermoelectric composition comprising a silicon-containing substrate coated with a thermoelectric film comprising a composition according to the formula [E₂MᵥO₂₊ᵥ]ₚ[Co_{1-y}T_{y}O₂] (3), wherein E represents one or a combination of metal atoms selected from the group consisting of alkali and alkaline earth metal atoms; M and T independently represent one or a combination of transition metal atoms; v represents 0, or a value greater than 0 and less than or equal to 1, or a value greater than 1, for the sum of M; y represents 0 or a value greater than 0 and less than 1 for the sum of T; and p represents a value greater than 0 and less than or equal to 1.

34. The thermoelectric composition according to claim 1, wherein said thermoelectric cobalt oxide film has a thermoelectric power factor of, or greater than, approximately 2 μW/cmK² at approximately room temperature.

35. The thermoelectric composition according to claim 34, wherein said thermoelectric cobalt oxide film has a thermoelectric power factor of, or greater than, approximately 16 μW/cmK² at approximately room temperature.

36. A thermal management device comprising:
(i) a thermoelectric component comprising a silicon-group substrate coated with a cobalt oxide film having thermoelectric properties; and
(ii) electrically conductive contacts connected to said thermoelectric component.

37. The thermal management device according to claim 36, wherein said cobalt oxide film has a composition comprising layers comprised of a composition according to the formula Co_{1-y}T_{y}O₂ (1), wherein T represents one or a combination of metal atoms selected from the group consisting of main group, transition and rare earth classes of metals, and y represents 0 or a value greater than 0 and less than 1 for the sum of T.

38. The thermal management device according to claim 37, wherein said cobalt oxide composition is according to the formula AₓCo_{1-y}T_{y}O₂ (2), wherein A represents one or a combination of metal atoms selected from the group consisting of monovalent, divalent, and trivalent metal atoms; T represents one or a combination of metal atoms selected from the group consisting of main group, transition and rare earth classes of metals; x represents a value greater than 0 and less than or equal to approximately 1 for the sum of A; and y represents 0 or a number greater than 0 and less than 1 for the sum of T.

39. The thermal management device according to claim 38, wherein A represents one or a combination of metal atoms selected from the group consisting of alkali and alkaline earth metals.

40. The thermal management device according to claim 39, wherein A represents one or a combination of metals selected from sodium, strontium, and calcium.

41. The thermal management device according to claim 40, wherein A represents calcium.

42. The thermal management device according to claim 37, wherein said cobalt oxide composition is according to the formula [E₂MᵥO₂₊ᵥ]ₚ[Co_{1-y}T_{y}O₂] (3), wherein E represents one or a combination of metal atoms selected from the group consisting of monovalent and divalent metal atoms; M and T independently represent one or a combination of metal atoms selected from the group consisting of main group, transition, and rare earth classes of metals; v represents 0, or a value greater than 0 and less than or equal to 1, or a value greater than 1, for the sum of M; y represents 0 or a value greater than 0 and less than 1 for the sum of T; and p represents a value greater than 0 and less than or equal to 1.

43. The thermal management device according to claim 42, wherein M represents cobalt.

44. The thermal management device according to claim 43, wherein E represents one or a combination of alkaline earth metal atoms.

45. The thermal management device according to claim 44, wherein E represents calcium.

46. The thermal management device according to claim 45, wherein said cobalt oxide film comprises a composition according to the formula [Ca₂CoᵥO₂₊ᵥ]ₚ[CoO₂] (4), wherein v represents 0, or a value greater than 0 and less than or equal to 1, or a value greater than 1; and p represents a value greater than 0 and less than or equal to 1.

47. The thermal management device according to claim 46, wherein p is approximately 0.62 and said cobalt oxide composition comprises a composition of approximate empirical formula Ca₃Co₄O₉.

48. A thermoelectric generator comprising:
(i) a thermoelectric component comprising a silicon-group substrate coated with a cobalt oxide film having thermoelectric properties; and
(ii) electrically conductive contacts connected to said thermoelectric component.

49. The thermoelectric generator according to claim 48, wherein said cobalt oxide film has a composition comprising layers comprised of a composition according to the formula Co_{1-y}T_{y}O₂ (1), wherein T represents one or a combination of metal atoms selected from the group consisting of main group, transition and rare earth classes of metals, and y represents 0 or a value greater than 0 and less than 1 for the sum of T.

50. The thermoelectric generator according to claim 49, wherein said cobalt oxide composition is according to the formula AₓCo_{1-y}T_{y}O₂ (2), wherein A represents one or a combination of metal atoms selected from the group consisting of monovalent, divalent, and trivalent metal atoms; T represents one or a combination of metal atoms selected from the group consisting of main group, transition and rare earth classes of metals; x represents a value greater than 0 and less than or equal to approximately 1 for the sum of A; and y represents 0 or a number greater than 0 and less than 1 for the sum of T.

51. The thermoelectric generator according to claim 50, wherein A represents one or a combination of metal atoms selected from the group consisting of alkali and alkaline earth metals.

52. The thermoelectric generator according to claim 51, wherein A represents one or a combination of metals selected from sodium, strontium, and calcium.

53. The thermoelectric generator according to claim 52, wherein A represents calcium.

54. The thermoelectric generator according to claim 49, wherein said cobalt oxide composition is according to the formula [E₂MᵥO₂₊ᵥ]ₚ[Co_{1-y}T_{y}O₂] (3), wherein E represents one or a combination of metal atoms selected from the group consisting of monovalent and divalent metal atoms; M and T independently represent one or a combination of metal atoms selected from the group consisting of main group, transition, and rare earth classes of metals; v represents 0, or a value greater than 0 and less than or equal to 1, or a value greater than 1, for the sum of M; y represents 0 or a value greater than 0 and less than 1 for the sum of T; and p represents a value greater than 0 and less than or equal to 1.

55. The thermoelectric generator according to claim 54, wherein M represents cobalt.

56. The thermoelectric generator according to claim 55, wherein E represents one or a combination of alkaline earth metal atoms.

57. The thermoelectric generator according to claim 56, wherein E represents calcium.

58. The thermoelectric generator according to claim 57, wherein said cobalt oxide film comprises a composition according to the formula [Ca₂CoᵥO₂₊ᵥ]ₚ[CoO₂] (4), wherein v represents 0, or a value greater than 0 and less than or equal to 1, or a value greater than 1; and p represents a value greater than 0 and less than or equal to 1.

59. The thermoelectric generator according to claim 58, wherein p is approximately 0.62 and said cobalt oxide composition comprises a composition of approximate empirical formula Ca₃Co₄O₉.

60. A method for altering the thermal characteristics of a device, the method comprising:
(i) supplying a thermoelectric component with an electrical current capable of producing a suitable thermal response in said thermoelectric component; and
(ii) providing a mode of heat transfer between said thermoelectric component and said device;
said thermoelectric component comprising a silicon-group substrate coated with a cobalt oxide film having thermoelectric properties.

61. The method according to claim 60, wherein said silicon-group substrate is comprised of zerovalent silicon.

62. The method according to claim 60, wherein said silicon-group substrate is comprised of silicon oxide.

63. The method according to claim 60, wherein said cobalt oxide film has a composition comprising layers comprised of a composition according to the formula Co_{1-y}T_{y}O₂ (1), wherein T represents one or a combination of metal atoms selected from the group consisting of main group, transition and rare earth classes of metals, and y represents 0 or a value greater than 0 and less than 1 for the sum of T.

64. The method according to claim 63, wherein said cobalt oxide composition is according to the formula AₓCo_{1-y}T_{y}O₂ (2), wherein A represents one or a combination of metal atoms selected from the group consisting of monovalent, divalent, and trivalent metal atoms; T represents one or a combination of metal atoms selected from the group consisting of main group, transition and rare earth classes of metals; x represents a value greater than 0 and less than or equal to approximately 1 for the sum of A; and y represents 0 or a number greater than 0 and less than 1 for the sum of T.

65. The method according to claim 64, wherein A represents one or a combination of metals selected from sodium, strontium, and calcium.

66. The method according to claim 66, wherein A represents calcium.

67. The method according to claim 63, wherein said cobalt oxide composition is according to the formula [E₂MᵥO₂₊ᵥ]ₚ[Co_{1-y}T_{y}O₂] (3), wherein E represents one or a combination of metal atoms selected from the group consisting of monovalent and divalent metal atoms; M and T independently represent one or a combination of metal atoms selected from the group consisting of main group, transition, and rare earth classes of metals; v represents 0, or a value greater than 0 and less than or equal to 1, or a value greater than 1, for the sum of M; y represents 0 or a value greater than 0 and less than 1 for the sum of T; and p represents a value greater than 0 and less than or equal to 1.

68. The method according to claim 67, wherein M represents cobalt.

69. The method according to claim 68, wherein E represents one or a combination of alkaline earth metal atoms.

70. The method according to claim 69, wherein E represents calcium.

71. The method according to claim 70, wherein said cobalt oxide composition is according to the formula [Ca₂CoᵥO₂₊ᵥ]ₚ[CoO₂] (4), wherein v represents 0, or a value greater than 0 and less than or equal to 1, or a value greater than 1; and p represents a value greater than 0 and less than or equal to 1.

72. The method according to claim 71, wherein v is approximately 1 and p is in a range of approximately 0.6 to 0.7.

73. The method according to claim 72, wherein p is approximately 0.62 and said cobalt oxide composition is of approximate empirical formula Ca₃Co₄O₉.

74. A method for generating electrical energy from a heat source, the method comprising providing a mode of heat transfer between a thermoelectric component and said heat source, thereby generating electrical energy in said thermoelectric component; said thermoelectric component comprising a silicon-group substrate coated with a cobalt oxide film having thermoelectric properties.

75. The method according to claim 74, further comprising connecting said thermoelectric component with an electrical power receiver capable of using or storing electrical energy generated by the thermoelectric component.

76. The method according to claim 74, wherein said cobalt oxide composition comprises layers comprised of a composition according to the formula Co_{1-y}T_{y}O₂ (1), wherein T represents one or a combination of metal atoms selected from the group consisting of main group, transition, and rare earth classes of metals, and y represents 0 or a value greater than 0 and less than 1 for the sum of T.

77. The method according to claim 76, wherein said cobalt oxide composition is according to the formula AₓCo_{1-y}T_{y}O₂ (2), wherein A represents one or a combination of metal atoms selected from the group consisting of monovalent, divalent, and trivalent metal atoms; T represents one or a combination of metal atoms selected from the group consisting of main group, transition and rare earth classes of metals; x represents a value greater than 0 and less than or equal to approximately 1 for the sum of A; and y represents 0 or a number greater than 0 and less than 1 for the sum of T.

78. The method according to claim 77, wherein A represents one or a combination of metals selected from sodium, strontium, and calcium.

79. The method according to claim 78, wherein A represents calcium.

80. The method according to claim 74, wherein said cobalt oxide composition is according to the formula [E₂MᵥO₂₊ᵥ]ₚ[Co_{1-y}T_{y}O₂] (3), wherein E represents one or a combination of metal atoms selected from the group consisting of monovalent and divalent metal atoms; M and T independently represent one or a combination of metal atoms selected from the group consisting of main group, transition, and rare earth classes of metals; v represents 0, or a value greater than 0 and less than or equal to 1, or a value greater than 1, for the sum of M; y represents 0 or a value greater than 0 and less than 1 for the sum of T; and p represents a value greater than 0 and less than or equal to 1.

81. The method according to claim 80, wherein M represents cobalt.

82. The method according to claim 81, wherein E represents one or a combination of alkaline earth metal atoms.

83. The method according to claim 82, wherein E represents calcium.

84. The method according to claim 83, wherein said cobalt oxide composition is according to the formula [Ca₂CoᵥO₂₊ᵥ]ₚ[CoO₂] (4), wherein v represents 0, or a value greater than 0 and less than or equal to 1, or a value greater than 1; and p represents a value greater than 0 and less than or equal to 1.

85. The method according to claim 84, wherein v is approximately 1 and p is in a range of approximately 0.6 to 0.7.

86. The method according to claim 85, wherein p is approximately 0.62 and said cobalt oxide composition comprises a composition of approximate empirical formula Ca₃Co₄O₉.

87. A method for growing an oxide film on silicon-group substrates, the method comprising depositing said oxide film on a silicon-group substrate pre-coated with a buffer oxide layer comprised of a cobalt oxide composition.

88. The method according to claim 87, wherein said substrate is comprised of zerovalent silicon.

89. The method according to claim 87, wherein said substrate is comprised of silicon oxide.

90. The method according to claim 87, wherein said substrate is comprised of zerovalent silicon having a silicon oxide surface.

91. The method according to claim 87, wherein said substrate is comprised of glass.

92. The method according to claim 87, wherein said cobalt oxide composition comprises layers comprising a composition according to the formula Co_{1-y}T_{y}O₂ (1), wherein T represents one or a combination of metal atoms selected from the group consisting of main group, transition, and rare earth classes of metals, and y represents 0 or a value greater than 0 and less than 1 for the sum of T.

93. The method according to claim 92, wherein said cobalt oxide composition is according to the formula AₓCo_{1-y}T_{y}O₂ (2), wherein A represents one or a combination of metal atoms selected from the group consisting of monovalent, divalent, and trivalent metal atoms; T represents one or a combination of metal atoms selected from the group consisting of main group, transition, and rare earth classes of metals; x represents a value greater than 0 and less than or equal to approximately 1 for the sum of A; and y represents 0 or a number greater than 0 and less than 1 for the sum of T.

94. The method according to, claim 93, wherein A represents one or a combination of metal atoms selected from the group consisting of alkali and alkaline earth metals.

95. The method according to claim 92, wherein said cobalt oxide composition is according to the formula [E₂MᵥO₂₊ᵥ]ₚ[Co_{1-y}T_{y}O₂] (3), wherein E represents one or a combination of metal atoms selected from the group consisting of monovalent and divalent metal atoms; M and T independently represent one or a combination of metal atoms selected from the group consisting of main group, transition, and rare earth classes of metals; v represents 0, or a value greater than 0 and less than or equal to 1, or a value greater than 1, for the sum of M; y represents 0 or a value greater than 0 and less than 1 for the sum of T; and p represents a value greater than 0 and less than or equal to 1.

96. The method according to claim 95, wherein M represents cobalt.

97. The method according to claim 96, wherein E represents one or a combination of alkaline earth metal atoms.

98. The method according to claim 97, wherein E represents calcium.

99. The method according to claim 98, wherein said layered cobalt oxide composition is according to the formula [Ca₂CoᵥO₂₊ᵥ]ₚ[CoO₂] (4), wherein v represents 0, or a value greater than 0 and less than 1, or a value greater than 1; and p represents a value greater than 0 and less than or equal to 1.

100. The method according to claim 99, wherein v is approximately 1 and p is in a range of approximately 0.6 to 0.7.

101. The method according to claim 100, wherein p is approximately 0.62 and said cobalt oxide composition comprises a composition of approximate empirical formula Ca₃Co₄O₉.
